(19) United States
(12) Patent Application Publication
(10) Pub. No.: US 2025/0087432 A1
(43) Pub. Date: Mar. 13, 2025

(54) ELECTRICAL SWITCH DEVICES

(71) Applicant: Leviton Manufacturing Co., Inc., Melville, NY (US)

(72) Inventors: Vikramsinh P. BHOSALE, Westbury, NY (US); Eugene FRID, Great Neck, NY (US); Nicolae BODRUG, Wantagh, NY (US); Constantin DIAC, Glen Cove, NY (US); Robert CANNETTI, Lindenhurst, NY (US)

(73) Assignee: Leviton Manufacturing Co., Inc., Melville, NY (US)

(21) Appl. No.: 18/724,102

(22) PCT Filed: Jan. 7, 2022
(86) PCT No.: PCT/US2022/011524

§ 371 Date: Jun. 25, 2024

(51) Int. Cl. H01H 9/54; G01B 7/30; G01D 5/14; G01R 19/00; H01H 9/20

(52) U.S. Cl. CPC H01H 9/54; G01B 7/30; G01D 5/145; G01R 19/0092; H01H 9/20

(57) ABSTRACT

Electrical devices, such as electrical switch devices, include a printed circuit board (PCB) that includes a communication circuit configured to communicate with a remote device and a processing circuit, a magnet, and a magnetic sensor configured to sense a magnetic field emanating from the magnet, where rotation of the handle between a first position and a second position causes rotational motion of at least one of the magnet and the magnetic sensor, the rotational motion repositioning the magnet and the magnetic sensor relative to each other, and where the magnetic sensor is configured to sense the repositioning and output a signal to the processing circuit indicative of a position of the handle.

### BACKGROUND

Electrical devices, such as safety disconnect switches, are often used in industrial applications to selectively couple loads, such as machinery, motors, lights, fans, pumps, generators and the like, to power sources. These electrical devices are designed to operate, and often do operate, in harsh conditions such as wet, dusty, or corrosive environments. As a result, the electrical devices and any device coupled thereto require frequent manual inspection and maintenance to ensure safe and effective operation. In many instances, maintenance problems are not detected until after damage has occurred. Further, routine manual inspections require a significant investment in manhours. As a result, electrical devices such as, for example, safety disconnect switches and mechanical interlocks, may be provided having components that can monitor operating conditions of the electrical device, or any device coupled thereto, while also being connected to remote devices to provide remote monitoring of the electrical device to facilitate more efficient preventative maintenance.

### SUMMARY

Shortcomings of the prior art are overcome and additional advantages are provided through the provision of electrical devices, such as electrical switch devices. In one embodiment of an electrical switch device for supplying power to a load, the electrical switch device includes (i) a printed circuit board (PCB), the PCB comprising a communication circuit configured to communicate with a remote device and a processing circuit; (ii) a handle configured to rotate between a first position and a second position; (iii) a load switch arranged and configured to open and close to selectively supply power to the load; (iv) a magnet; and (v) a magnetic sensor configured to sense a magnetic field emanating from the magnet. In such an electrical switch device, rotation of the handle between the first position and the second position causes rotational motion of at least one of the magnet and the magnetic sensor, the rotational motion repositions the magnet and the magnetic sensor relative to each other, and the magnetic sensor is configured to sense the repositioning and output a signal to the processing circuit indicative of a position of the handle.

Rotation of the handle between the first position and the second position may cause the load switch to open and close. For instance, rotation of the handle can cause rotation of a component that opens and closes the load switch.

In embodiments, the electrical switch device further includes a component that is configured to rotate based on rotation of the handle between the first position and the second position, where the magnet is coupled to the component. The component may be a handle shaft, and the magnet may be disposed at least partially embedded in the handle shaft. Rotation of the handle between the first position and the second position may cause rotational motion of the magnet to move the magnet closer to, or farther from, the magnetic sensor.

Additionally or alternatively, the electrical switch device can include a stop plate disposed between the magnet and the magnetic sensor. The stop plate can include an opening, and when the handle is positioned in the first position, the magnet may be closer to the opening of the stop plate than when the handle is positioned in the second position. Based on the handle being in the first position, the magnet may be in one position that is at least partially aligned with the opening of the stop plate, and based on the handle being in the second position the magnet may be in another position that is out-of-alignment with the opening of the stop plate. In embodiments, the magnetic sensor is configured to sense the magnetic field emanating from the magnet in the one position based on the handle being in the first position, where the intensity of the magnetic field emanating from the magnet as sensed by the magnetic sensor is greater when the handle is in the first position and the magnet is in the one position as compared to when the handle is in the second position and the magnet is in the another position. The one position, in which the magnet is at least partially aligned with the opening of the stop plate, can correspond to an OFF position in which the load switch is open, and the another position, in which the magnet is out-of-alignment with the opening of the stop plate, can correspond to an ON position in which the load switch is closed to provide the power to the load. In embodiments, the stop plate includes material with a shielding property (such as steel) that shields the magnetic field sensor from the magnetic field emanating from the magnet when the handle is positioned in the second position, and the opening of the stop plate is positioned and configured such that when the handle is positioned in the first position, the magnetic field sensor senses the magnet field emanating from the magnet passes through the opening in the stop plate.

Additionally or alternatively, the electrical switch device can include a stacked board arrangement in which the magnet, the magnetic sensor, and the PCB are provided in a stacked configuration coupled together and at least partially enclosed in a cover of the electrical switch device.

In embodiments, the load switch is configured to accept a plurality of input power phase conductors. The electrical switch device can further include a current sensor configured to sense a respective level of current through each phase conductor of the plurality of input power phase conductors and communicate, via a PCB of the current sensor, the sensed respective level of current through each phase conductor to another component of the electrical switch device.

Additionally, in accordance with embodiments described herein, an electrical device is provided that includes a cover subassembly configured for operatively coupling with a handle. The cover subassembly includes (i) a printed circuit board (PCB), the PCB comprising a communication circuit configured to communicate with a remote device and a processing circuit; (ii) a magnet; and (iii) a magnetic sensor configured to sense a magnetic field emanating from the magnet. In such an electrical switch device, the cover subassembly is configured such that rotation of the handle between the first position and the second position causes rotational motion of at least one of the magnet and the magnetic sensor, the rotational motion can reposition the magnet and the magnetic sensor relative to each other, and the magnetic sensor is configured to sense the repositioning and output a signal to the processing circuit indicative of a position of the handle.

In embodiments, the cover subassembly further includes a component configured to rotate based on rotation of the handle between the first position and the second position, where the magnet is coupled to the component. The component may be a handle shaft, for instance, and the magnet may be disposed at least partially embedded in the handle shaft.

The cover subassembly may be configured such that rotation of the handle between the first position and the second position causes rotational motion of the magnet to move the magnet closer to, or farther from, the magnetic sensor.

In embodiments, the cover subassembly further includes a stop plate disposed between the magnet and the magnetic sensor. The stop plate can include an opening. The cover subassembly may be configured such that when the handle is positioned in the first position, the magnet is closer to the opening of the stop plate than when the handle is positioned in the second position.

Additionally or alternatively, the cover subassembly may be configured such that, based on the handle being in the first position, the magnet is in one position that is at least partially aligned with the opening of the stop plate, and, based on the handle being of the second position, the magnet is in another position that is out-of-alignment with the opening of the stop plate.

In embodiments, the magnetic sensor is configured to sense the magnetic field emanating from the magnet in the one position based on the handle being in the first position, where the intensity of the magnetic field emanating from the magnet as sensed by the magnetic sensor is greater when the handle is in the first position and the magnet is in the one position as compared to when the handle is in the second position and the magnet is in the another position. The one position, in which the magnet is at least partially aligned with the opening of the stop plate, can correspond to an OFF position, and the another position, in which the magnet is out-of-alignment with the opening of the stop plate, can correspond to an ON position. In embodiments, the stop plate includes material with a shielding property (such as steel) that shields the magnetic field sensor from the magnetic field emanating from the magnet when the handle is positioned in the second position, and the opening of the stop plate is positioned and configured such that when the handle is positioned in the first position, the magnetic field sensor senses the magnet field emanating from the magnet passes through the opening in the stop plate.

Additionally or alternatively, the cover subassembly can include a stacked board arrangement in which the magnet, magnetic sensor, and the PCB are provided in a stacked configuration coupled together and at least partially enclosed in a cover of the cover subassembly.

In embodiments, the electrical also includes the handle, a base subassembly that includes a DIN rail and a load switch coupled to the DIN rail, the load switch arranged and configured to open and close to selectively supply power to a load, and a switch rod coupling the load switch to the cover subassembly. Rotation of the handle between the first position and the second position can cause rotation of the switch rod to open and close the load switch.

In embodiments, the load switch is configured to accept a plurality of input power phase conductors. The electrical switch device can further include a current sensor configured to sense a respective level of current through each phase conductor of the plurality of input power phase conductors and communicate, via a PCB of the current sensor, the sensed respective level of current through each phase conductor to another component of the electrical switch device.

Additional features and advantages are realized through the concepts described herein.

### BRIEF DESCRIPTION OF THE DRAWINGS

Aspects described herein are particularly pointed out and distinctly claimed as examples in the claims at the conclusion of the specification. The foregoing and other objects, features, and advantages of the disclosure are apparent from the following detailed description taken in conjunction with the accompanying drawings in which:

FIG. 1 depicts an exploded, perspective view of an example mechanical interlock electrical switch device;

FIG. 2 illustrates an exploded, perspective view of another example mechanical interlock electrical switch device;

FIG. 3 depicts an example printed circuit board architecture;

FIG. 4 depicts a front perspective view of an example electrical switch device, in accordance with aspects described herein;

FIG. 5 depicts a partial exploded front perspective view of an example electrical switch device, in accordance with aspects described herein;

FIGS. 6A and 6B depict front and rear perspective views, respectively, of an example cover subassembly in accordance with aspects described herein;

FIG. 7 depicts a partial exploded front perspective view of an example electrical switch device with an exploded base subassembly, in accordance with aspects described herein;

FIGS. 8A-8B depict isolated rear perspective views of a handle shaft and magnet arrangement, in accordance with aspects described herein;

FIGS. 9A-9B depict front and rear perspective views of an example stop plate in accordance with aspects described herein;

FIG. 10 depicts an isolated perspective view of a stop plate and handle shaft, in accordance with aspects described herein;

FIG. 11 depicts an exploded perspective view of a stacked design in accordance with aspects described herein;

FIG. 12 depicts a rear perspective view of a cover subassembly in accordance with aspects described herein;

FIG. 13 presents another rear perspective view of a cover subassembly in accordance with aspects described herein;

FIGS. 14A-14D depict an example embodiment of a current sensor in accordance with aspects described herein;

FIGS. 15A-15B depict another example embodiment of a current sensor in accordance with aspects described herein;

FIG. 16 depicts another example embodiment of a current sensor in accordance with aspects described herein; and

FIGS. 17-18 depict example mount positions of a current sensor, in accordance with aspects described herein.

### DETAILED DESCRIPTION

Described herein are safety disconnect switches (collectively “electrical switch devices”), components thereof, and related electrical devices for informing of status relating to supply of electricity to connected equipment. A safety disconnect switch may also be referred to herein as an “electrical switch device”, “disconnect device”, “electrical disconnect”, or just “disconnect”, and may or may not incorporate separate mechanical interlock features as plug-connector components.

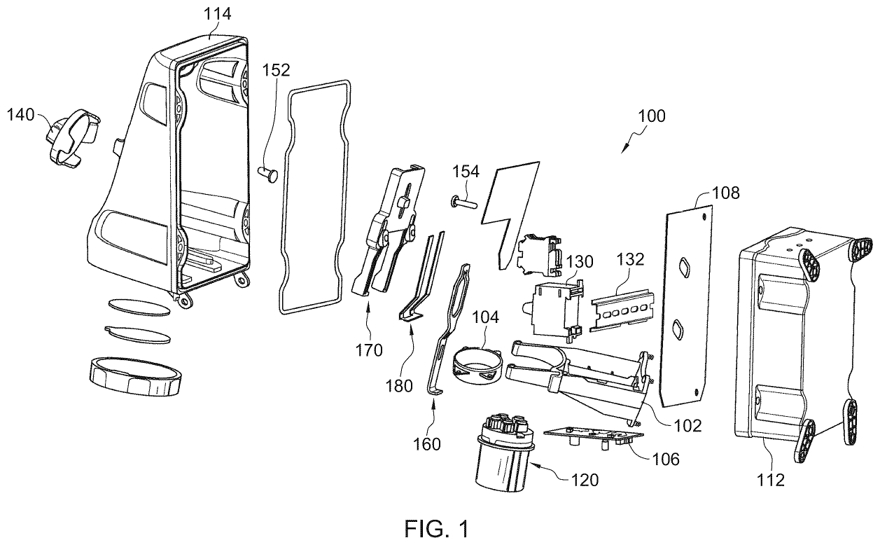

FIG. 1 depicts an exploded, perspective view of an example mechanical interlock electrical switch device. Mechanical interlock 100 includes an enclosure (formed of a front housing portion or cover 114 and a rear housing portion or base 112), a connector 120 for coupling to, for example, a plug (not pictured) to supply power to a downstream connected electrical device (a ‘load’), an internal load switch 130 (also referred to herein as an electrical switch) for selectively energizing and de-energizing the connector 120, an external handle assembly 140 movable between an ON position and an OFF position to control the internal load switch 130, and a handle shaft 152 for rotationally coupling the external handle assembly 140 to the internal load switch 130. In the illustrated embodiment, the handle shaft 152 cooperates with a switch shaft 154 to form of a two-piece shaft so that the external handle assembly 140 may be operatively coupled to the load switch 130 via the handle shaft 152 and switch shaft 154. The handle shaft 152 may be rotationally coupled to the switch shaft 154 so that rotation of the external handle assembly 140 rotates the handle shaft 152 which rotates the switch shaft 154 which rotates/actuates the load switch 130.

Slider plate 170, latch spring 180 and interlock latch 160 may collectively form an interlock latch assembly. In use, the interlock latch assembly is selectively movable between a first position and a second position. The interlock latch assembly is arranged and configured to be operatively associated with the connector 120 and the external handle assembly 140 so that when the interlock latch assembly is in the first position, the interlock latch assembly prevents rotation of the external handle assembly 140, and when the interlock latch assembly is in the second position, the interlock latch assembly permits rotation of the external handle assembly 140. In one embodiment, the interlock latch assembly is movable between the first position and the second position via insertion of the plug into the connector 120. That is, insertion of the plug into the connector 120 contacts and moves the interlock latch assembly from the first position to the second position.

Mechanical interlock 100 also includes a DIN rail 132 for receiving the load switch 130, and a contact carrier bracket 102 and adapter 104 for coupling the connector 120 relative to the enclosure. The mechanical interlock 100 may also include one or more printed circuit boards (PCBs) such as, for example, PCB 106 coupled to the contact carrier bracket 102.

As noted, the enclosure includes base 112 and cover 114, although it is envisioned that the enclosure may be manufactured from a greater or fewer number of portions. The enclosure may be manufactured from any suitable material including, for example, plastic, metal, or the like.

Given the tight space constraints within the enclosure and the number of components being positioned therein, assembly of the mechanical interlock 100 can be challenging. For example, wiring the connector 120, the internal load switch 130, and the PCB 106 can be challenging when those components are positioned within the side walls of the enclosure (e.g. walls of base 112).

To facilitate easier assembly, the mechanical interlock 100 includes a plate, carrier, platform, chassis, or the like (collectively referred to herein as a base plate without the intent to limit) 108. In use, the base plate 108 is arranged and configured to receive one or more components thereon so that the components can be initially coupled to the base plate 108 and wired to each other without the space constraints of the enclosure base 112. Thereafter, the base plate 108 including the components coupled thereon can be positioned within the enclosure and the base plate 108 can be coupled to the enclosure via, for example, one or more fasteners. In one example embodiment, the DIN rail 132 can be coupled to the base plate 108 and thereafter the internal load switch 130 can be coupled to the DIN rail 132. Alternatively, the internal load switch 130 can be coupled directly to the base plate 108 without the intervening DIN rail 132. Additionally, the contact carrier bracket 102 can be coupled to the base plate 108 and thereafter the connector 120 can be coupled to the contact carrier bracket 102. The internal load switch 130 can also be electrically coupled or wired to the connector 120. In addition, PCB 106 may be coupled to the contact carrier bracket 102 and electrically coupled or wired to the connector 120 and/or internal load switch 130 as required. All of this assembly can be completed without the space constraints of the enclosure. Thereafter, once the components have been coupled to the base plate 108 and/or electrically coupled or wired to each other, the base plate 108 and the components mounted thereto can be positioned within the enclosure base 112 and one or more fasteners can be used to couple the base plate 108 to the enclosure base 112). In this manner the base plate 108 enables a stand-alone subassembly or module of components, including the load switch and others, to be assembled and/or wired together prior to positioning within the enclosure. The base plate 108 is arranged and configured as a platform for component assembly so that components and any electrical wiring can be assembled onto the base plate 108 without the enclosure base 112 sidewalls limiting access to connection and access points. Once completed, the base plate 108 and the components assembled thereto can be positioned into the walled enclosure and coupled thereto.

The base plate 108 may be manufactured from any suitable material including, for example, metal such as, for example, galvanized steel. As illustrated, the base plate 108 may have a rectangular shape although it is envisioned that the base plate 108 may have any other suitable shape and/or size. In addition, although illustrated as a single component, it is envisioned that the base plate may be formed of multiple pieces.

The mechanical interlock 100 may be adapted and configured with a particular connector 120 for receiving a corresponding plug. The connector 120, depending on the plug's configuration, voltage, etc., may have a different size and/or clock position. It is not uncommon for manufacturers to make and store a number of differently sized contact carrier brackets corresponding to a number of different connectors. That is, under current manufacturing techniques, a unique contact carrier bracket may be required for every unique plug and connector configuration. However, given their overall shape, manufacturing of contact carrier brackets can be complex and expensive. The adapter 104 therefore is used for operatively coupling the contact carrier bracket 102 to the connector 120, which receives the plug. In this manner, a single contact carrier bracket 102 can be manufactured, stored, and incorporated into every mechanical interlock regardless of which connector 120 is being used. Individual adapters 104 corresponding to each connector 120 can be manufactured and stored, and then, based on the required connector 120, the corresponding adapter 104 can be selected and coupled to the contact carrier bracket 102.

The depicted embodiment of contact carrier bracket 102 includes a first end for coupling to, for example, the base plate 108 or the enclosure base 112, and a second end arranged and configured for coupling to the adapter 104, which is arranged and configured to receive the connector 120. As illustrated, the second end may include first and second arms defining a space therebetween. The adapter 104 may be in the form of a ring having an outer circular shape and an interior opening. In use, the adapter 104 may be arranged and configured to be at least partially received within the space formed between the first and second arms, although it is envisioned that the adapters and the contact carrier bracket may take many different forms. The adapter 104 may be coupled to the contact carrier bracket 102 by any suitable mechanism (adhesive, bonding, etc.) and/or one or more fasteners. Thereafter, the connector 120 may be positioned within the interior opening formed in the adapter 104.

Each adapter 104 may be color coded, with each color corresponding to a specific connector 120, which adds a level of failsafe to the selection and assembly process. That is, as will be appreciated by one of ordinary skill in the art, plugs and their corresponding connectors 120 can be provided in any number of configurations. For example, different current levels (e.g., 16 amperes (A), 20 A, 30 A, 32 A, 60 A, 100 A, 150 A, 200 A, 400 A, or the like), different voltage levels (e.g., 125 volts (V), 240V, 250V, 480V, 600V, 100/130V, 125/250V, 102/208V, 200/250V, 208/250V, 277/480V, 346-415V, 347/600V, 380/415V, 440-460V, and others), and/or different ground pin locations (e.g., depending on the individual plug and connector, the ground pin, located in the connector, is positioned in a particular location along the circumference of the connector to ensure that the connector is only able to receive a corresponding plug, referred to herein as a “clock position”).

In use, each adapter 104 can be color coded to a specific connector 120 to ease selection of the correct adapter 104 so that, during assembly, depending on the configuration of the connector 120 being assembled into the enclosure, a color-coded adapter 104 can be selected thereby simplifying the assembly process and/or quality control verification. That is, the adapters 104 can be color-coded for a specific voltage and/or clock position.

Additionally, the adapter 104 and the contact carrier bracket 102 may include an alignment, key or keying feature (e.g., a Poke-Yoke mechanism) incorporated therebetween (alignment, key and keying are used interchangeably herein without the intent to limit) to ensure that the adapter 104 is properly positioned relative to the contact carrier bracket 102 when coupled thereto. In one example embodiment, the adapter 104 and the contact carrier bracket 102 include a first key to ensure that the adapter 104 can only be coupled to the contact carrier bracket 102 in a single, proper position. In use, the connector 120 and the adapter 104 may include a key incorporated therebetween to ensure that the connector 120 is properly positioned relative to the adapter 104 when coupled thereto. In one example embodiment, the connector 120 and the adapter 104 include a second key to ensure that the connector 120 can only be coupled to the adapter 104 in a single, proper position. In this manner, by keying the position of the connector 120 relative to the adapter 104 and by keying the position of the adapter 104 relative to the contact carrier bracket 102, proper positioning (e.g., proper clock positioning of the connector 120) is ensured. By preventing incorrect installation of the adapter 104 relative to the contact carrier bracket 102 and/or relative to the connector 120, incorrect final position of the connector 120 relative to the contact carrier bracket 102 is prevented. That is, the adapters 104 are preferably arranged and configured to ensure that the adapter 104, and hence the connector 120 received thereby, can only be coupled to the contact carrier bracket 102 in a single orientation (e.g., orientation can be defined by orienting the ground pin in the connector 120 relative to the contact carrier bracket 102 at a clock position such as, for example, 6 o'clock, 7 o'clock, or the like).

In use, the various keys may be arranged and configured so that if the connector 120 was improperly coupled to the adapter 104 such as, for example, the connector 120 was improperly rotated relative to the adapter 104, and/or the adapter 104 was improperly coupled to the contact carrier bracket 102 such as, for example, the adapter 104 was inserted in a flipped or reverse position and/or if the adapter 104 was installed in an incorrect rotational position relative to the contact carrier bracket 102, the keys will not align with the associated surfaces of the connector 120 and/or the carrier bracket 102, thus preventing incorrect coupling of the connector 120 to the adapter 104 and/or the adapter 104 to the contact carrier bracket 102.

It should be appreciated that numerous variations of keys may be utilized to ensure that the connector 120 can only be coupled to the adapter 104 and that the adapter 104 can only be coupled to the contact carrier bracket 102 in a single, proper orientation. As such, the keys may be any suitable mechanism or keying feature now known or hereafter developed so long as improper coupling and/or orientation of the connector 120 relative to the adapter 104 and/or the adapter 104 relative to the contact carrier bracket 102 is prevented. As such, the present disclosure should not be limited to any particular key described and illustrated herein unless specifically claimed.

In examples, the adapter 104 may include one or more male features, bosses, projections, or the like (used interchangeably herein without the intent to limit) and the contact carrier bracket 102 may include one or more female features, openings, holes, or the like (used interchangeably herein without the intent to limit), arranged and configured to mate with the boss formed on the adapter 104, or vice-versa. In this manner, the boss extending from the adapter 104 can only be received within the hole formed in the contact carrier bracket 102 when the adapter 104 is properly positioned relative to the contact carrier bracket 102, thus ensuring easy and failsafe assembly. That is, in this manner, each configuration of adapter 104 can only be installed in a single orientation (e.g., cannot be accidentally or unintentionally flipped and/or rotated, thus changing, for example, the clock position of the ground pin in the connector 120), thus, ensuring proper orientation and/or positioning of the adapter 104 relative to the contact carrier bracket 102, and hence proper positioning of the clock position or ground pin location of the connector 120.

In one example embodiment, the adapter 104 may include a first boss protruding therefrom and the contact carrier bracket 102 may include a first hole for receiving the first boss extending from the adapter 104. The boss and the hole may be arranged and configured so that the first boss is only receivable by the first hole when the adapter 104 is properly positioned and/or orientated relative to the contact carrier bracket 102. By providing a key, the adapter 104 cannot be incorrectly coupled relative to the contact carrier bracket 102. In use, the key may include different sized bosses and holes, different shaped bosses and holes, etc.

In one example embodiment, the connector 120 may include one or more features, recesses, flat portions, or the like (used interchangeably herein without the intent to limit) and the adapter 104 may include one or more features, bosses, projections, flat portions, or the like (used interchangeably herein without the intent to limit), arranged and configured to mate with a feature formed on the connector 120, or vice-versa. For example, the adapter 104 may include one or more projections extending inwardly therefrom for mating with one or more recesses formed in the connector 120. The projection may include a threaded bore for receiving a fastener for coupling the connector 120 to the adapter 104. In this manner, the feature formed on the adapter 104 can only mate with the feature formed on the connector 120 when the connector 120 is properly positioned relative to the adapter 104, thus ensuring easy and failsafe assembly. That is, in this manner, each configuration of connector 120 can only be installed in a single orientation (e.g., cannot be accidentally or unintentionally rotated, thus changing, for example, the clock position of the ground pin in the connector 120), thus, ensuring proper orientation and/or positioning of the connector 120 relative to the adapter 104, and the adapter 104 relative to the contact carrier bracket 102, and hence proper positioning of the clock position or ground pin location of the connector 120.

As previously mentioned, the mechanical interlock 100 may also include one or more PCBs such as, for example, PCB 106 coupled to the contact carrier bracket 102. The PCB(s) 106 may be coupled (e.g., mounted) to the contact carrier bracket 102 to provide an increased level of protection from, for example, the environment (e.g., water, etc.) and to provide an increased level of protection from damage associated, for example, with dropping the device, transporting, etc. That is, when coupled to the enclosure 110, the contact carrier bracket 102 may include a top surface, a bottom surface, and laterally extending sidewalls defining a recess. In use, the PCB 106 may be coupled to the bottom surface of the contact carrier bracket 102 within the recess in-between the sidewalls. In use, the contact carrier bracket 102 may include one or more features such as, for example, shelves, ribs, bosses, etc. to allow installation and support of the PCB 106. In use, the contact carrier bracket 102 provides protection to the PCB 106 from, for example, damage during assembly, wiring or installation, protection from accumulated debris and water, protection during transportation, etc. In use, the PCB 106 may be protected by the sidewalls of the contact carrier bracket 102. The sidewalls acting as strengthening or stiffening ribs for increased robustness of the bracket 102. As such, the PCB 106 may be protected and/or partially encased by the contact carrier bracket 102 thus protecting the PCB 106 from water, damage, or the like by forming a housing type envelope around the PCB 106.

The PCB 106 may be coupled to the bottom surface of the contact carrier bracket 102, and be sized and configured to fit within the space envelope formed between the sidewalls of the contact carrier bracket 102. In this manner, the PCB 106 can be protected by the contact carrier bracket 102 from, for example, environmental and physical damage, thus ensuring a more robust design. Additionally, the PCB 106 can be installed and wired to the contact carrier bracket 102 before final bracket 102 installation (e.g., facilitates creation of a sub-assembly), as described above. In addition, the PCB 106 may include one or more keys between, for example, the PCB 106 and the contact carrier bracket 102 to ensure installation in only one position, as described above.

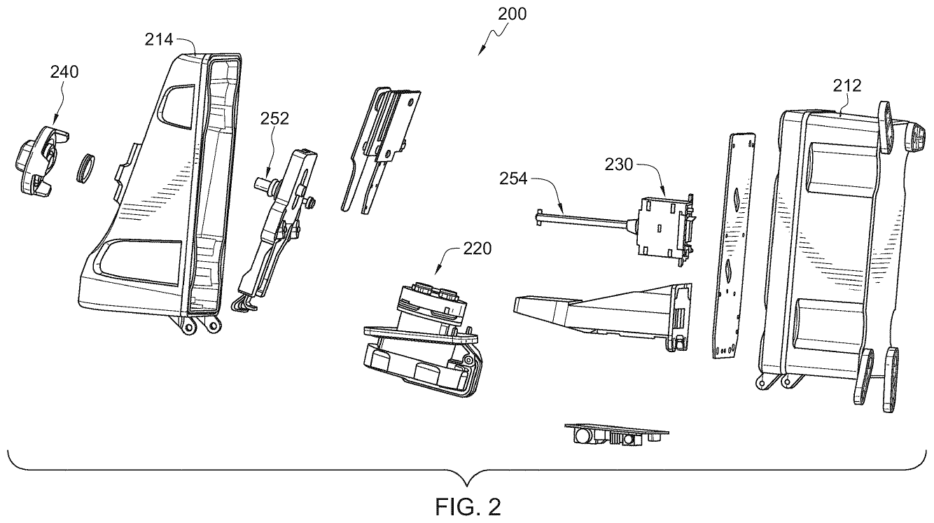

These and other aspects are also described with reference to FIG. 2, illustrating an exploded, perspective view of another example mechanical interlock electrical switch device. Although FIGS. 1 and 2 both depict mechanical interlock devices, aspects described herein may be used with any suitable electrical device in any form, for example mechanical interlocks, disconnect switches, a pin and sleeve devices including a plug device and a receptacle or connector, an inlet devices, rotatably actuatable switches, or the like.

Referring to FIG. 2, mechanical interlock 200 can be used to supply power to connected devices via, for example, a pin and sleeve device such as, for example, a plug that can be connected to the mechanical interlock 200 for selectively supplying power to a downstream electrical device. Interlock 200 includes an enclosure (formed of a front housing portion or cover 214 and a rear housing portion or base 212), a connector 220 for coupling to, for example, a plug (not shown), an internal load switch 230, an external handle assembly 240, and a handle shaft 252 for rotationally coupling the external handle assembly 240 to the internal load switch 230. In the illustrated embodiment, the handle shaft 252 cooperates with a switch shaft 254 to form of a two-piece shaft so that the external handle assembly 240 may be operatively coupled to a handle shaft 252 and the load switch 230 may be coupled to a switch shaft 254.

The mechanical interlock 200 may receive power through one or more power input conductors/lines (not shown) and may supply power to, for example, a plug coupled to the connector 220. The external handle assembly 240 is typically mounted on a front of the cover 214 and may be connected to the load switch 230 through, for example, the handle and switch shafts 252, 254 to operate the actuating mechanism of the load switch 230. In use, the external handle assembly 240 may be rotationally locked to the load switch 230. Here, a shaft coupling the two is in the form of a two-piece shaft so that the external handle assembly 240 may be operatively coupled to a handle shaft 252 and the load switch 230 may be coupled to switch shaft 254. The handle shaft 252 may be rotationally coupled to the switch shaft 254 so that rotation of the external handle assembly 240 rotates the handle shaft 252 which rotates the switch shaft 254 which rotates/actuates the load switch 230 to selectively supply and disconnect power from the connector 220 and hence the plug and the downstream electrical device.

As illustrated, the enclosure may be made up of a rear housing portion or base 212 and a front housing portion or cover 214, although it is envisioned that the enclosure may be manufactured from more or less portions. In addition, the enclosure may be manufactured from any suitable material including, for example, plastic, metal, or the like.

In use, the downstream electrical device may be energized or de-energized depending on the position of the handle assembly 240. Accordingly, the mechanical interlock 200 is “ON” (e.g., supplying power to the connected, downstream electrical device) when the plug is coupled to the connector 220 and the handle assembly 240 is in an “ON” position. When the handle assembly 240 is moved to an “OFF” position, the actuating mechanism of the load switch 230 will have been moved to open the contacts, so that power to the associated electrical device is disconnected. In general, the handle assembly 240 is rotated ninety-degrees to transition the mechanical interlock 200 between the ON and OFF positions.

The mechanical interlock 200 may also include an interlock latch assembly (not pictured) selectively movable between a first position and a second position, and, as described above, arranged and configured to be operatively associated with the connector 220 and the external handle assembly 240 so that when the interlock latch assembly is in the first position, the interlock latch assembly prevents rotation of the external handle assembly 240, and when the interlock latch assembly is in the second position, the interlock latch assembly permits rotation of the external handle assembly 240. The interlock latch assembly may be movable between the first position and the second position via insertion of the plug into the connector 220 such that insertion of the plug into the connector 220 contacts and moves the interlock latch assembly from the first position to the second position.

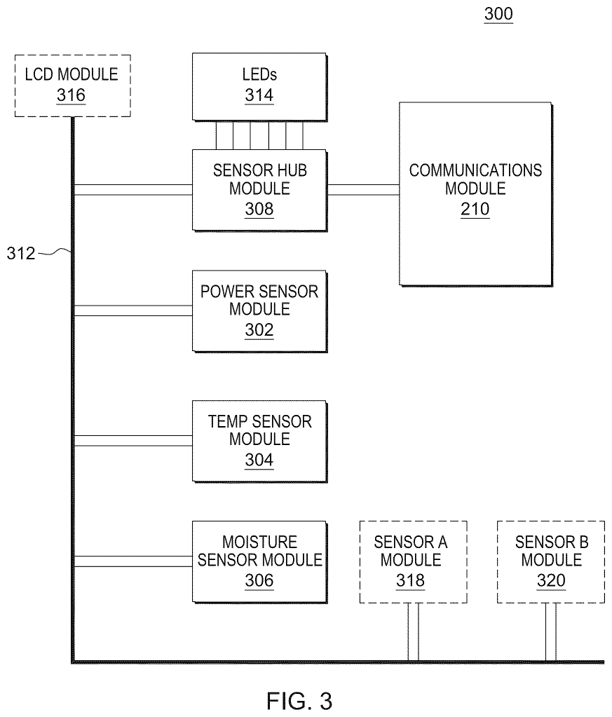

FIG. 3 depicts an example embodiment of a printed circuit board architecture. The printed circuit board (PCB) architecture 300 enables interconnection of components of an electrical switch device operating within an industrial environment. The PCB architecture 300 further enables the components of the device to connect to a remote computer network, a remote device, a remote cloud service or platform, and/or the Internet. The PCB architecture 300 may represent connections between components mounted on one or more PCBs, and therefore architecture 300 may be implemented by/on one or more PCBs. Architecture 300 may be referred to herein as simply a “PCB”, though it should be understood that the architecture could be implemented by any number of (one or more) physical PCBs in communication with each other.

The PCB architecture 300 may be provided in any type of electrical device including, but not limited to, electrical switch devices (including, for instance, those with mechanical interlocks) described herein. The architecture 300 provides a unified and scalable approach for adding or removing electrical components that may operate within or as part of the electrical switch device. The architecture 300 provides connectivity to any type of constituent electrical component such as, for example, a sensor that may collect data that may be analyzed to facilitate predictive maintenance and improved performance of the electrical switch device and/or any other device coupled thereto. The architecture can be provided within electrical switches that are configured to operate in any of various three-phase configurations. As examples, in one embodiment, the architecture 300 can be provided within an electrical switch device that is configured to operate in a three-phase Delta configuration and in another embodiment, the architecture 300 can be provided within an electrical switch device that is configured to operate in a three-phase Wye configuration.

As shown in FIG. 3, the architecture 300 may include a power sensor module 302, a temperature sensor module 304, a moisture sensor module 306, a sensor hub module 308, and a communications module 310. The power sensor module 302 may detect a condition or operational state of a power connection and/or a ground connection to the electrical switch device. For example, the power sensor module 302 may monitor power and ground continuity, power loss, or other disruptions in power line connections provided to the electrical switch device or provided by the electrical switch device. The temperature sensor module 304 may detect a temperature of the electrical switch device and/or a temperature of an operating environment of the electrical switch device. The moisture sensor module 306 may detect an amount of moisture within the electrical switch device and/or within the operating environment of the electrical switch device.

The sensor hub module 308 may be any type of processing circuit (controller, processor, logic device, etc.) including, for example, any programmable logic device (PLD), application specific integrated circuit (ASIC), general purpose processor, or logic circuitry. In one embodiment, the sensor hub module 308 may be a microcontroller unit (MCU).

The power sensor module 302, temperature sensor module 304, moisture sensor module 306, and sensor hub module 308 may be interconnected by a communications bus 312. The communications bus 312 enables data or other communications to be transmitted between the power sensor module 302, the temperature sensor module 304, the moisture sensor module 306, and the sensor hub module 308. For example, data generated by the power sensor module 302 may be transmitted to the sensor hub module 308 over the communications bus 312. In one embodiment, the communications bus 312 may be a 2-wire isolated serial bus configured and/or operating according to the Inter-Integrated Circuit (I2C) protocol. In general, the communications bus 312 may provide connectivity with a reduced number of wires that isolates low voltage components of the architecture 300.

Each sensor within the architecture 300—for example, each of the power sensor module 302, the temperature sensor module 304, and the moisture sensor module 306—may generate a respective signal(s) indicative of detected conditions or collected data and may transmit the generated signal(s) to the sensor hub module 308. The sensor hub module 308 may then receive and process the signals. The sensor hub module 308 may then process and/or analyze any data provided in a signal provided by a sensor of the architecture 300. The sensor hub module 308 may adjust or control operation of any component of the architecture 300 or any other component coupled to the sensor hub module 308 based on the information provided by the received signals.

As an example, the sensor hub module 308 may transmit control instructions or other information to the power sensor module 302 based on data provided to the sensor hub module 308 from the power sensor module 302. Similarly, the temperature sensor module 304 and the moisture sensor module 306 may interact with the sensor hub module 308 to exchange data or other information. In this way, data generated by any of the power sensor module 302, the temperature sensor module 304, and the moisture sensor module 306 may be provided to the sensor hub module 308 and the sensor hub module 308 may direct operation of any of the power sensor module 302, the temperature sensor module 304, or the moisture sensor module 306.

The sensor hub module 308 may provide processed data to the communications module 310. The communications module 310 may transmit any information or data received from the sensor hub module 308 to any remote device, remote computer network, or remote cloud service or platform. The communications module 310 may provide a wired communications interface operating according to any known wired communication standard or protocol. The communications module 310 may also or alternatively provide a wireless communications interface operating according to any known wireless communications standard or protocol. In one embodiment, the communications module 310 may be a Wi-Fi module. In one embodiment, the sensor hub module 308 and the communications module 310 may communicate over a universal asynchronous receiver-transmitter (UART) connection. The communication may be according to any of various data communication protocols, an example of which is Modbus.

The communications module 310 allows data or other information provided to the sensor hub module 308 by the power sensor module 302, the temperature sensor module 304, the moisture sensor module 306 or any other constituent component of the electrical switch device coupled to the communications bus 312 to be offloaded for processing or analysis. Further, the communications module 310 allows data or other information (e.g., control instructions) from a remote device to be received and provided to the sensor hub module 308. The sensor hub module 308 may then direct operation of the power sensor module 302, the temperature sensor module 304, and the moisture sensor module 306 or any other constituent component of the electrical switch device coupled to the communications bus 312 based on data received from a remote device or network.

The architecture 300 allows the sensor hub module 308 to receive data from any number of components coupled to the communications bus 312. Further, the architecture 300 allows data provided to the sensor hub module 308 to be transmitted remotely to enable remote monitoring of the electrical switch device. An operational state of the electrical switch device may be determined by a remote device based on the provided data. Preventive maintenance of the electrical switch device may then be provided based on knowledge of the operating state of the electrical switch device. The architecture 300 also allows remote data or other remote communications to be received by the sensor hub module 308 and then distributed to any component coupled to the communications bus 312. In this way, the electrical switch device having the architecture 300 may operate as an intelligent device by interconnecting constituent components of the device and connecting the constituent components to a remote device, a remote device, the Internet, and/or a cloud service or platform. In turn, the connectivity provided by the architecture 300 may provide improved monitoring and maintenance of the electrical switch device or any constituent component thereof.

The operational status of the electrical switch device or any component thereof may also be indicated locally using light emitting diodes (LEDs) 314. The LEDs 314 may be, for example, positioned on an outer portion of an enclosure of the electrical switch device. The LEDs 314 may be operated to indicate an operation status of the electrical switch device or any constituent component thereof.

The architecture 300 may optionally include a liquid crystal display (LCD) module 316 (shown in phantom in FIG. 3). The LCD module 316 may display visual information such as information regarding the operational status of the electrical switch device or any constituent component thereof. The LCD module 316 may include a touchscreen or a touch-sensitive display. Accordingly, the LCD module 316 may provide visual information and/or may receive an input from a user.

The architecture 300 provides an easily scalable and upgradable means to interconnect constituent components to the sensor hub module 308. A first additional sensor module 318 and a second additional sensor module 320 are shown in phantom to indicate the ability to enhance, augment, upgrade, or scale the architecture 300 to meet the needs of the user. The first and second additional sensors 318 and 320 may be added to the communications bus 312 to facilitate interconnectivity with the sensor hub module 308 without the need to add new or separate wiring or to implement additional communication technologies. In general, the architecture 300 allows for any number of components (e.g., sensors, displays, circuits, etc.) to be coupled to the communications bus 312. For example, multiple sensors of the same type (e.g., two or more temperature, humidity, or moisture sensors) may be coupled to the communications bus 312 and configured to communicate with the sensor hub module 308. Further, a variety of different types of sensors beyond those illustrated in FIG. 3 may be coupled to the communications bus 312 and configured to communicate with the sensor hub module 308 including, for example, a pressure sensor, a vibrational sensor, a sound sensor, a thermal array sensor or array or sensors, a current sensor, and/or a magnetic sensor. In this manner, the architecture 300 may provide a universal, safe, and reduced wiring approach to connecting devices in an industrial application that may be modularly expanded to meet needs for any application.

The moisture sensor module 306 may be or include a moisture detection sensor. By way of specific example, the moisture detection sensor may be or include a water detection sensor to detect water. Further description of the moisture detection sensor is provided by way of example with reference to a “water detection sensor”, though it is understood that these aspects may be equally applicable to any kind of moisture detection, not just water. A water detection sensor can detect accumulation of water inside enclosures containing high voltage circuits or wiring such as, for example, an electrical switch device. The water detection sensor may provide an alert or alarm if an amount of water inside of the enclosure exceeds a predetermined level, thereby enabling action to be taken to reduce the likelihood of compromised safety or equipment failure. The water detection sensor may be provided within or on a component of an electrical switch device, such as the enclosure or housing such that the water detection sensor is provided within or on a surface of the enclosure. In embodiment, the component may be a PCB such that the water detection sensor is provided on the PCB which may be mounted inside of an electrical switch device. In an embodiment, the water detection sensor may be provided within a device that is mounted on a wall with the water detection sensor oriented either vertically or horizontally.

The water detection sensor can generate and transmit a signal (for instance to a communication module) indicating that water inside of an enclosure in which the water detection sensor is positioned has exceeded a predetermined level. In embodiments, the signal may be an alarm signal and may be transmitted over any type of communication link including, for example, a wired or wireless communication link. In one embodiment, the water detection sensor may include or may be coupled to one or more LEDs that may provide a visual alarm regarding the detection of water that exceeds a predetermined level.

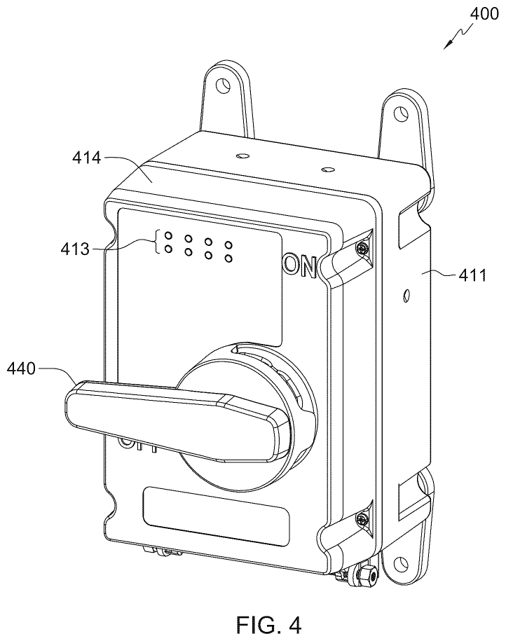

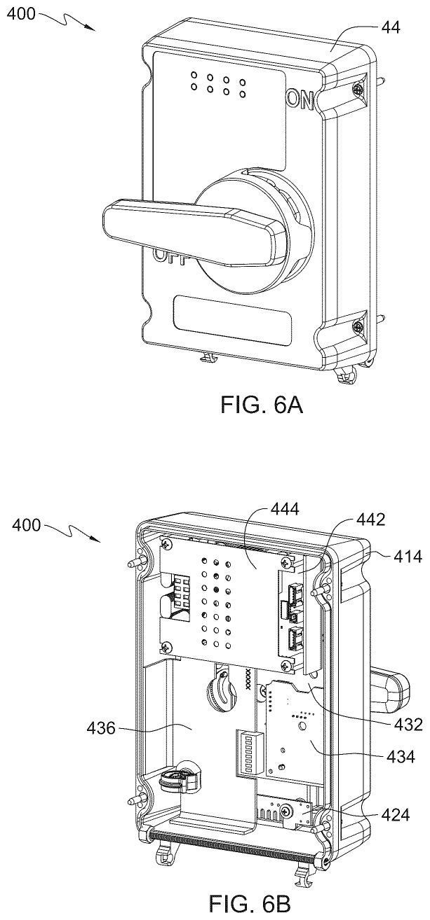

FIGS. 4-13 present additional embodiments of electrical devices to incorporate and use aspects described herein. FIG. 4 depicts a front perspective view of an example electrical switch device 400 for electrically coupling between a power source (via a line wire(s)) and a load (via load wire(s)). The device 400 includes an assembled enclosure, comprising front cover 414 and back covers 411, and handle assembly 440 (sometimes referred to herein as just “handle”). Front cover 414 is also depicted in FIGS. 6A and 6B showing front and rear perspective views, respectively, of a cover subassembly. Status indicators 413 include light-emitting diode (LED) lights that provide YES/NO indications of signals present for each of the three phases and on each of the line side (i.e. line wire(s)) and the load side (i.e. load wire(s)) of the internal load switch. These statuses can be deduced based on voltage measurements, for instance. The status indicators can also include an indicator of whether a ground connection is present and an error indicator. The error indicator can utilize one or more colors and indicate any desired error condition(s), for instance an abnormally high temperature in the device or the presence of liquid in the device. The error indicator could also be used for diagnostic purposes.

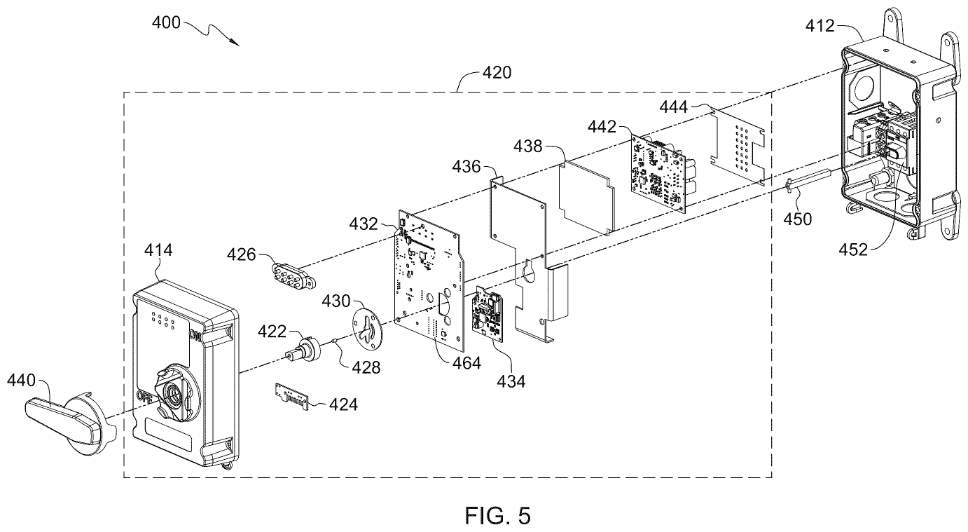

FIG. 5 depicts a partial exploded front perspective view of example electrical switch device 400 in accordance with aspects described herein. Device 400 includes handle assembly 440, base subassembly 412, and cover subassembly 420 (shown exploded here). It is understood that some components have been omitted from the depiction.

Cover subassembly 420 includes front cover 414, handle shaft 422, liquid sensor assembly 424, lens 426, magnet 428, stop plate 430, display board 432, communications board 434, heat sink 436, thermal pad 438, power PCB 442, and insulator 444.

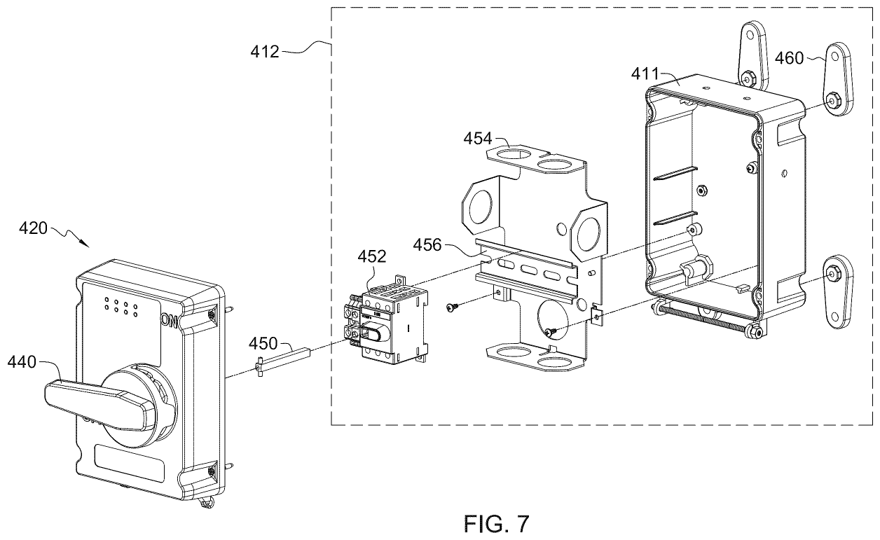

The components of cover subassembly 420 when assembled are stacked and fastened (e.g. with screws) in/to cover 414, and handle assembly 440 is mounted on a front of the cover 414 (e.g. as in FIG. 4, 6A, 6B) for physical engagement with, and actuation (e.g. via shaft component(s)) of, load switch 452 of the base subassembly 412. FIG. 7 depicts a partial exploded front perspective view of electrical switch device 400 with a cover subassembly 420, handle assembly 440, switch rod 450, and exploded base subassembly 412. The base subassembly 412 includes internal load switch 452 arranged and configured to open and close to selectively supply power to the load, base plate 454 on which DIN rail 456 is mounted and to which load switch 452 mounts, back cover 411, and mounting feet 460.

The electrical switch device enables an operator to rotate the handle between ON and OFF positions to turn ON and OFF the internal load switch accordingly and control provision of power to the load. In addition, aspects of the electrical switch device can be used to inform end users of ON/OFF status, voltage/power presence (both load and line side), and possible issues related to, e.g., voltage imbalance of the electrical supply to the load connected to the device, or loss of ground. In these examples (e.g. in contrast to FIGS. 1 and 2), the switch device is hardwired on both the line and load sides rather than relying on a plug connector for electrical coupling to the load.

Liquid sensor assembly 424 can also be leveraged to inform end users about water (or other moisture) accumulation due to condensation, accidental water seepage, and the like. In embodiments, a visual indication (via the LED lights), communication to a remote device, or an alert/alarm can be presented in particular situations, such as when a particular water height is reached, as an example, thereby enabling action to be taken to reduce the likelihood of compromised safety or equipment failure. The user, once informed, has an opportunity to avoid an unsafe condition by opening the device and removing the water, for instance.

In accordance with aspects described herein, improvements of functionality and serviceability, including conversion of existing switch devices into smart switches, are achieved as described herein in part using mechanical and electrical PCB arrangements.

Referring again to FIG. 5, external handle assembly 440 is mounted on a front of the enclosure (e.g. front of cover 414) and may be connected to the load switch 452 via, for example, a shaft component (e.g. handle shaft 422 and switch rod/shaft 450) to operate the actuating mechanism of the load switch 452. The external handle assembly 440 may be rotationally locked to the load switch 452 via the shaft such that rotational movement of the handle assembly 440 between the first position and second position causes the shaft (handle shaft 422, switch rod 450) to rotate, which in turn actuates/rotates a component of the load switch 452 to open/close the load switch and thereby selectively supply and disconnect power to load(s) downstream electrical device 400. Internal load switch 452 includes an actuating mechanism that moves to open and close internal contacts so that power to the load is disconnected or connected accordingly.

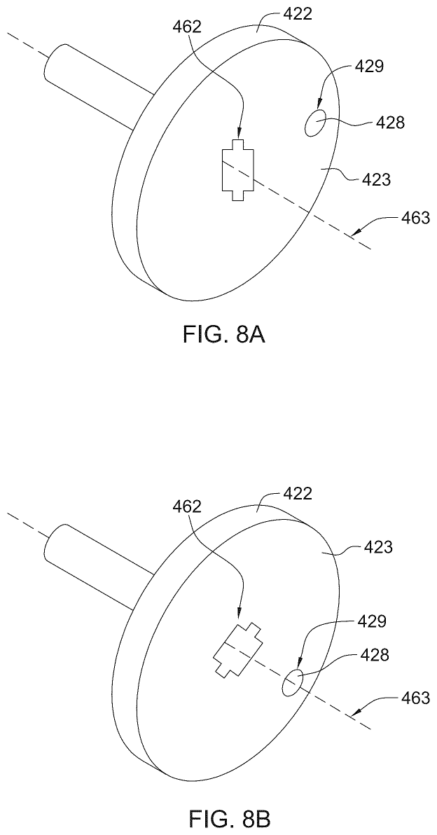

FIGS. 8A-8B depict isolated rear perspective views of the handle shaft 422 and magnet 428. Handle shaft 422 includes at its rear-facing side a hole or other opening 429 to accommodate magnet 428 when the cover subassembly is assembled. The magnet 428 is coupled to the handle shaft 422, in this example sitting partially or wholly embedded in handle shaft 422. In embodiments, the magnet 428 is substantially cylindrical and sits embedded in the handle shaft 422 such that an exposed face of the cylindrical magnet is substantially flush with surface 423 of the rear-facing side of handle shaft 422.

Handle shaft 422 includes another opening 462 at the central axis 463 of handle shaft 422. Opening 462 is configured to accept one end of the switch rod 450 to operatively couple with the switch rod 450 so that the two are rotationally locked, i.e. rotation of handle shaft 422 rotates switch rod 450.

Opening 429 for the magnet 428 is offset from central axis 463 toward a periphery of handle shaft 422 in this example. With magnet 428 embedded at least partially within handle shaft 422, clockwise or counter-clockwise rotation of the handle shaft 422 about its central axis 463 will carry the magnet in a corresponding clockwise or counter-clockwise direction about the central axis. FIG. 8A shows the magnet in an approximate 2:00 position and FIG. 8B shows the magnet in the 5:00 position after the handle shaft 422 has been rotated counter-clockwise 90 degrees about the central axis 463.

As explained in further detail below, there is a corresponding magnetic field sensor 464 (see FIG. 5; also referred to as a “magnetic sensor”) of the display board 432. Rotation of the handle shaft 422 causes the magnet 428 to move relative to the magnetic sensor 464. The magnetic sensor 464 may in some embodiments remain in a fixed-position on account of its coupling or incorporation on/in the display board 432. The magnetic sensor 464 is configured to sense, and senses, a magnetic field emanating from the magnet 428. The magnetic sensor 464 can provide output signal(s) that distinguish between rotational positions of the handle shaft. For instance, the magnetic sensor 464 could detect the magnetic field emanating from the magnet 428 when the handle shaft 422 is in one rotational position (such as the position corresponding to the ON position of the handle) but not when the handle shaft is in another rotational position (such as the position corresponding to the ON position of the handle), for instance, and provide different outputs accordingly. In another example, the strength of the magnetic field detected when the handle shaft 422 is in the one rotational position is different than the strength when the handle shaft 422 is in the other rotational position. Accordingly the magnetic sensor 464 may be a Hall effect sensor. In a particular embodiment, the switch components are configured as described herein such that the magnetic sensor 464 detects the magnetic field of the magnet 428 when the handle is in the OFF position and does not detect the magnetic field of the magnet 428 when the handle is in the ON position. This may be aided by the stop plate 430 as described below. The stop plate can also serve a function of controlling rotational movement of the handle. That is, the stop plate 430 can include stopper portion(s) that physically control how far the handle can rotate in each direction and thereby prevent the handle from turning beyond set angular positions.

Display board 432 may include various components. Example such components are an LED module with functionality that includes LED functionality described above, for instance to display visual information such as information regarding the operational status of the electrical switch device or any constituent component thereof. Additionally, as noted, the display board can an incorporate magnetic sensor 464 to sense a magnetic field of magnet 428.

Communication board 434 may be any type of PCB that facilitates communication between the electrical switch device and remote devices, as described herein. In examples, the communication board 434 is a WiFi chip/board and/or one that uses the Modbus protocol for communication. The communication board 434 can be used to notify remote devices (smartphones or other computer systems) and users thereof of any data collected or sensed by electrical switch device, including any information that may be indicated by the LED indications. In examples, the communication board 434 is mounted to display board, e.g. as a ‘daughterboard’ thereof (see FIG. 6B).

Heat sink 436 and thermal pad 438 cooperatively provide heat sinking for components of the electrical switch device, for instance PCBs thereof, e.g. display board 423 and power PCB 442.

PCB(s), such as communication board 434, display board 432, and/or power PCB 442, can implement aspects of a PCB architecture such as is described above with reference to FIG. 2. In general, electrical switch devices can include one or more PCBs, where at least one includes a processing circuit and at least one is or includes a communication circuit configured for communicating with one or more remote devices.

Insulator 444 provides an insulating buffer between the base subassembly 412, particularly the base plate 454 thereof (see FIG. 7), and other components of the cover subassembly 420 having stacked components as described herein. The stacked components of the cover subassembly 420 can be, as depicted and described, mounted in/to the disconnect front cover (414) as opposed to the base (back cover 411) as part of the base subassembly 412. This potentially enables pre-existing disconnects to be upgraded to include aspects described herein relative to the cover subassembly 420.

When assembled, the components of the cover subassembly provide a stacked display board (432) and power board (442) arrangement. This differs from other approaches, such as those described above with reference to FIGS. 1 and 2, where coupled PCBs such as a moisture sensor and power board are mounted and provided in the base subassembly mounted to the baseplate thereof. In contrast, the display PCB 432, liquid sensor assembly 424, communication board 434, and power PCB 442 of electrical switch device 400 are mounted in a stacked PCB fashion as part of the cover subassembly 420. Screws may be used to assemble together components 414, 422, 424, 426, 428, 430, 432, 434, 436, 438, 442, and 444 (among other components) as a stacked subassembly of the cover subassembly 420. The cover subassembly 420 can then plug into or fit with a corresponding base subassembly 412 having a load switch. A switch rod 450 can be provided to work with the base subassembly 412 as a retrofit arrangement and allowing pre-existing disconnects (e.g. incorporating a base subassembly with a load switch) to be upgraded to cooperate with a cover subassembly, such as 420.

In accordance with these aspects, the communication board 434 is plugged into the display board 432. Other such ‘daughter’ boards providing differing functionality could also be coupled to display board 432, depending on what kind of interface or other functionality is desired. Accordingly, these other boards can similarly be incorporated into the stacked board arrangement of the cover subassembly 420, removing them from the base subassembly and enabling greater flexibility and options for serviceability and replacement of existing ‘dumb’ electrical switch devices to convert them into smart switch devices. In general, any PCB desired for features described herein could be provided in the cover subassembly such that the cover subassembly could work with a variety of existing or to-be-developed base subassemblies.

As mentioned above, the magnet 428 placed into the handle shaft 422 cooperates with the magnetic sensor 464 mounted on the display board 432 for the magnetic sensor 464 to provide an indication of the ON/OFF status/state of the device 400. Disposing the magnet 428 on or in a component that rotates with rotation of the switch handle results in selective positioning of the magnet 428 depending on the rotational position of the handle, which is tied to an ON/OFF status of the load switch on account of the rotational coupling of the handle to the load switch via shaft component(s). As described with reference to the stop plate 430, the design thereof can shield the magnetic field sensor 464 from the magnetic field emanating from the magnet 428, preventing the magnetic field sensor 464 from sensing the magnetic field depending on the position of the magnet 428 relative to the magnetic field sensor 464.

In this manner, the magnetic field sensor 464 can sense the magnetic field when the handle is in the OFF position (and therefore internal load switch 452 is open) and may be unable to sense the magnetic field—or senses it differently, for instance at a less intensity-when the handle is in the ON position (and therefore internal load switch 452 is closed) on account of interference imparted by the stop plate interposed between the sensor 464 and the magnet 428.

This configuration ensures that the position of the handle assembly 440 is known with certainty. The position of the handle assembly 440 as ascertained from the output of the magnetic sensor could be sufficient to conclude the state of the load switch (e.g. open or closed). This state can be compared, monitored, etc., and, if necessary, one or more fault indications can be provided. Optionally, this state could be compared to other indicators of the electrical state of the load switch 452 (e.g., ON versus OFF), and, if necessary, one or more fault indications can be provided. The magnet 428 may be a permanent magnet or the like that may be coupled to a rotating element (the handle shaft 422 as one example) that is directly tied in terms of its rotational position to the position of the external handle assembly 440 so that, in use, the magnet 428 can be moved into and out of sensing range relative to a magnetic sensor. The magnetic sensor is, for example, a hall-effect or other type of magnetic sensor 464. In some examples presented herein, rotation of the handle shaft 422 between first and second positions (e.g. corresponding to ON and OFF positions) moves the magnet 428 into and out of sensing range relative to the sensor 464 located on, for example, a PCB board 432.

When the magnet 428 is located at least a given distance away from the sensor 464, the magnet 428 may be out of a sensing range of the sensor 464 and thus the magnetic flux from the magnet 428 may be out of range from the sensor 464 and the sensor 464 will not detect any presence of the magnet. Then when the magnet 428 moves toward the sensor 464 on account of the rotation of, e.g., the handle shaft 422, to reposition the magnet relative to the sensor 464, the magnetic flux from the magnet 428 may be within a given distance or range of the sensor 464 to trigger the sensor 464 or otherwise be detectable to the sensor 464. The signal generated by the magnetic flux created when the magnet 428 is positioned within range of the sensor 464 can be transmitted to a processor (not shown) located on, for example, a PCB, such as the display board 432 or the power PCB 442, or on another PCB. The processor can then communicate the information to remote devices via the communication board 434. Optionally, if the load switch is capable of sensing and providing its state, the processor could be communicatively coupled to the load switch 452 and receive from the load switch a signal corresponding to the state of the load switch (e.g., ON or OFF). In this manner, the processor can receive data concerning the state of the load switch 452 such as, for example, whether power is being supplied and can compare the position of the handle assembly 440 (as informed by the magnetic sensor 464) to the electrical state of the load switch 452 to determine if one or more fault conditions exists, and if so, to provide an indication of fault. The indication could be provided by controlling ON/OFF state of one or more LEDs on the enclosure, or could be one or more wireless signals, texts, emails, or the like transmitted by the electrical switch device.

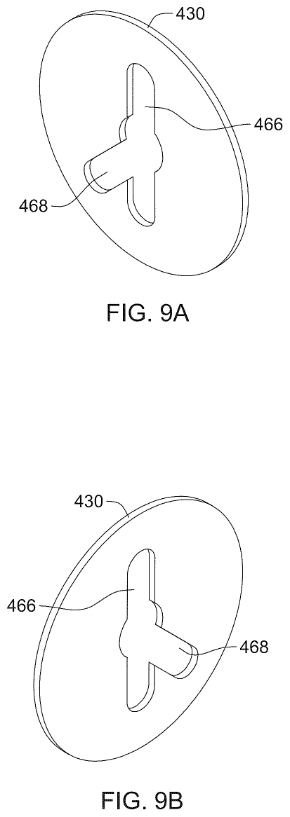

Additionally or alternatively, the stop plate 430 may be configured to shield the magnetic field sensor from the magnetic field emanating from magnet 428 depending on the position of the magnet, to enhance magnetic coupling/detection between the magnet 428 and the magnetic sensor 464 on the display board 432. FIGS. 9A-9B depict front and rear perspective views of an example stop plate in accordance with aspects described herein. Stop plate 430 includes a central slot 466 and an opening 468. The opening 468 in this example is an angled slot that is conjoined with and protrudes from central slot 466. The stop plate 430 may be arranged relative to the magnet 428 (see FIG. 5) such that when the handle 440 is rotated into a first position (e.g. the OFF position; FIG. 8B), the magnet is closer to the opening 468 of the stop plate 430 than when the handle 440 is rotated into the second position (e.g. the ON position; FIG. 8A). For instance, the stop plate 430 may be positioned relative to the magnet 428 such that the opening 468 and magnet 428 are at least partially in alignment when the handle 440 is rotated into the first position. That is, the position of the magnet in this position may be such that it is at least partially aligned with the opening of the stop plate 430, in examples. This enables at least a portion of the magnetic field emanating from the magnet to pass through the opening to reach the magnetic field sensor when the handle is in the first position. The stop plate can be made of material with a shielding property that shields/blocks/masks the magnetic field from penetrating through the stop plate material so that when the magnet is moved farther from the opening in the stop plate, the magnetic field of the magnet is unable to reach the magnetic field sensor on account of the shielding property of the stop plate material and because the magnet is farther from the opening and the magnetic field emanating therefrom does not pass with enough intensity through the opening to the sensor.

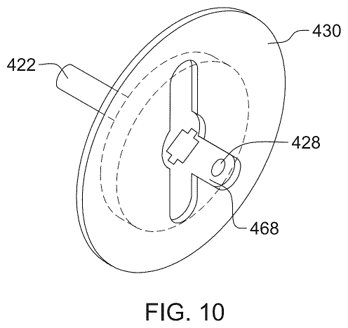

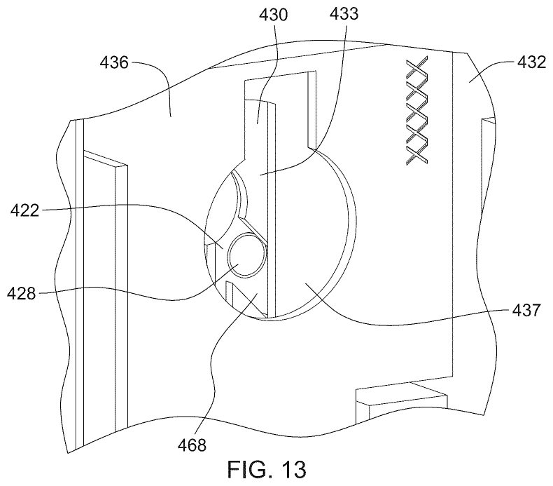

FIG. 10 depicts an isolated perspective view of the stop plate and handle shaft showing partial alignment of the magnet in the handle shaft to the opening of the stop plate. The perspective view of FIG. 10 depicts the stop plate 430 viewed from the display board side of the assembly. Behind stop plate 430 is handle shaft 422 with embedded magnet 428, which is visible through opening 468 of the stop plate 430. The stop plate 430 may be disposed between the magnet 428 and the magnetic sensor 464 of the display board 432 (see FIG. 5, FIG. 13). Thus, in examples, the stop plate 430 is interposed between the magnetic sensor 464 and the magnet 428, and the handle 440 may be rotated into the first position so that the magnetic sensor 464 has line-of-sight to magnet 428 through opening 468, enabling at least some of the magnetic field to pass through to the magnetic field sensor. In other examples there is no such line-of-sight between the magnet 428 and magnetic sensor 464 but proximity of the magnet 428 to the opening of the stop plate when the handle shaft 422 is in the first position is such that the magnetic sensor 464 senses the magnet 428 in that first position. For instance, when the handle 440 is positioned in the first position, the magnet 428 is closer to the opening 468 of the stop plate 430 than when the handle 440 is positioned in the second position, which may be out-of-alignment with the opening 468 of the stop plate 430.

As noted, the stop plate 430 may be made of material with a shielding property that shields/blocks/masks a magnetic field from penetrating through the stop plate material. A stop plate with no opening may block the magnetic field from reaching the sensor altogether, regardless of the handle position, such that the sensor would not detect the magnet and therefore cannot distinguish between the handle positions. However, the opening 468 may be positioned and configured (i.e. size, shape, etc.), so that the shielding effect of the stop plate is ineffective to prevent the magnetic sensor from sensing the magnet in the first position on account of the opening 468 provided in the stop plate. The shape, size, and position of the opening can all influence the extent to which the magnetic field is able to pass through the opening. In embodiments, it is desired for the opening to be configured and positioned such that the magnetic field is sensed by the sensor when the handle is in the first position but not when the handle is in the second position.

When the handle 440 is to turned to the second position and the magnet 428 is out-of-alignment with the opening 468 of the stop plate 430 and positioned farther therefrom, the configuration of the stop plate 430 shields the magnetic field emanating from the magnet 428 from detection by the magnetic field sensor 464. For example, the magnetic field sensor is sufficiently shielded by the stop plate 430 (the magnetic field does not penetrate the stop plate material) and the magnet is sufficiently far enough away from the opening that the sensor cannot sense the magnetic field emanating from the magnet.

In these examples, the intensity of the magnetic field sensed by the magnetic sensor on the display board is greater when the handle is in the OFF position. In embodiments, when the handle is in the ON position, the magnetic sensor does not sense the magnetic field of the magnet or senses the field at a lower intensity than the intensity it senses when the handle is in the OFF position. Thus, with the handle shaft and therefore magnet in a first position (e.g., corresponding to the OFF position of the handle), the magnet may be positioned within a sensing range of the magnetic sensor so that the magnet interacts with the magnetic sensor such that the magnetic sensory provides a signal that the external handle is in the OFF position. With the handle shaft and therefore magnet in the second position (e.g., corresponding to the ON position of the handle), the magnet is moved counterclockwise so that the magnet may no longer be within range of the magnetic sensor and/or the magnetic emanating from the magnet may be sufficiently shielded by the stop plate, and therefore the magnet no longer interacts with the magnetic sensor, which thus provides no signal. Alternatively, it is envisioned that the magnet may be arranged and configured to interact with the magnetic sensor when in the ON position and not in the OFF position.

The magnetic sensing can be used to detect and inform of the position of the handle, which provides an indirect detection of an electrical connection of the load to the power source. This can be monitored to enable voltage measurements on the load side, for instance.

In these examples, the stop plate 430 does not rotate and it interferes with the magnetic sensor's sensing of the magnetic field of the magnet more when the handle is in the ON position than when it is in the OFF position. However, various embodiments can exist in which the magnet, stop plate, and/or magnetic sensor are disposed or positioned in different configuration(s) in which rotational movement of the handle causes a relative movement between two or more of these devices to enable the magnetic sensor to sense the position of the handle.

Therefore, components of the electrical switch device could be configured and disposed such that rotation of the handle between the first position and the second position causes rotational motion of the magnet and/or the magnetic sensor (i.e. one or both), in which the rotational motion repositions the magnet and the magnetic sensor relative to each other. The magnetic sensor can be configured to sense this repositioning and output a signal to a processing circuit indicative of a position of the handle. The processing circuit may be configured to interpret the signal to obtain/identify the position of the handle and therefore the electrical state (open/closed, or ON/OFF) of the load switch. In this manner, rotation of the handle imparts rotational movement of the magnet and/or sensor so that they become repositioned relative to each other.

In some embodiments, the magnet could be disposed anywhere on the handle side of the stop plate such that it rotates with rotation of the handle. An alternative to embedding the magnet in the handle shaft is to couple the magnet to (for instance dispose the magnet) in/on an end of the switch rod 450 that is accepted into an opening of the handle shaft 422. The switch rod 450, including its end engaged with the handle shaft, rotates with the handle shaft 422 when the handle is rotated, providing the rotational motion that maybe sensed by the magnetic sensor. Alternatively, in another embodiment the magnetic sensor is disposed on the handle side of the stop plate, the magnet is disposed on the load switch side of the stop plate, the magnetic sensor moves from one position to another with rotation of the handle, and thus the magnetic sensor is positioned relative to the magnet and opening such that the magnetic sensor is brought closer to the magnet and senses handle position on that basis.

Accordingly, the magnet may be coupled to a component (such as the handle shaft 422) that rotates with rotation of the handle, and alternatively the magnet may be coupled to a component the remains in a fixed position while the magnetic sensor is repositioned relative to the magnet when the handle is rotated. In yet other examples, the magnet and the magnetic sensor are both repositioned when the handle is rotated from a first position to a second position but the magnet and sensor move relative to each other such that the magnetic sensor can distinguish between the first and second positions.

In examples, the magnet coupled to a component by being at least partially embedded within the component (e.g. handle shaft). Additionally or alternatively the magnet could be fastened, adhered, attached, press-fit, fixed, etc. to the component, fully encapsulated within the component, or in any other way physically engaged, directly or indirectly, with the component such that they remain in a fixed position relative to each other.

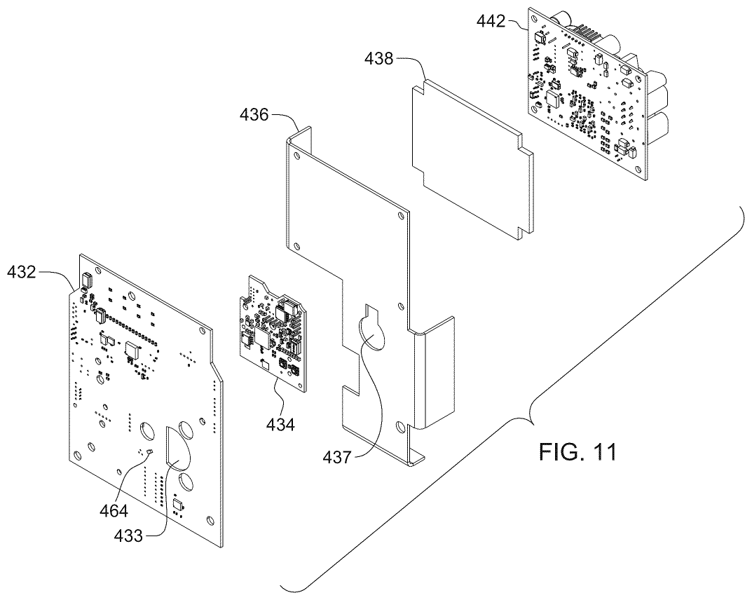

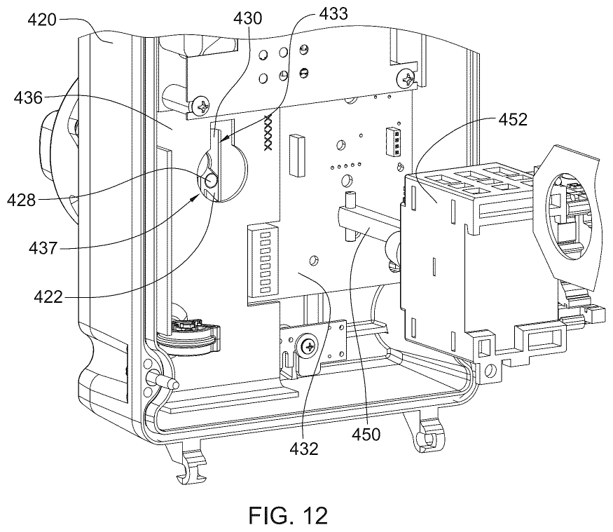

Aspects of the above are facilitated in part by a stacked design of the heat sink 436 and associated components between the display board 432 and the power board 442 to sink heat. FIG. 11 depicts an exploded perspective view of the display board 432, communication board 434, heat sink 436, thermal pad 438 and power PCB 442. Heat sink 436 is provided with hole 437 which is in at least partial alignment with hole 433 of display board to enable the switch rod 450 (not pictured) to pass through holes 437 and 433 and engage with the handle shaft 422 (not pictured). FIG. 12 depicts a rear perspective view of the cover subassembly 420, switch rod 450 and load switch 452. When the cover subassembly 420 is assembled to the base subassembly 412, the switch rod 450 passes through the opening 437 of the heat sink 436, opening 433 of the display board 432, and the central opening/slot 466 of the stop plate 430 to engage with the opening 462 (FIG. 8A) of the handle shaft 422. This configuration also enables a user to dismount the handle assembly 440 for possible replacement in situ.

Also visible in FIG. 12 is the magnet 428 embedded in handle shaft 422 and at least partially aligned with the angled slot opening 468 of the stop plate 430. FIG. 13 presents a close up rear perspective view of the alignment, in which magnet 428 embedded in handle shaft 422 is in substantial alignment with opening 468 of stop plate 420. This is viewable through opening 433 of display board 432 and opening 437 of heat sink 436. The magnetic sensor (not pictured) can be provided on the display board 432 substantially close to opening 468 to enable the magnetic sensor to sense the magnetic field in this position (e.g. the OFF position of the handle and therefore the load switch).

In such a stacked board arrangement, the magnet, the magnetic sensor, and the PCBs (432, 442 here) are provided in a stacked configuration coupled together such that they are enclosed in front cover 414 of the electrical switch device when assembled as in FIG. 6B.

Additional or alternative to a magnet-based approach for sensing movement, motion, and/or handle positioning, and switch opening/closing based thereon, one option is to mount a mechanical switch on a PCB (such as one of the aforementioned PCBs) that can be actuated physically according to (i.e. to comport with) the handle position (e.g. ON of OFF). Additionally or alternatively, an optical-based interrupter switch could be used for sensing movement, motion, and/or handle positioning, and switch opening/closing based thereon.

Electrical switch devices described herein are capable of accommodating a current sensor that can sense current of the power phase(s), each corresponding to a carrier wire connected to the load switch, and provide to local component(s) of the switch device and/or remote devices the values representative of the amount of current flowing through each of the phase(s) during the operation of the load connected to the device.

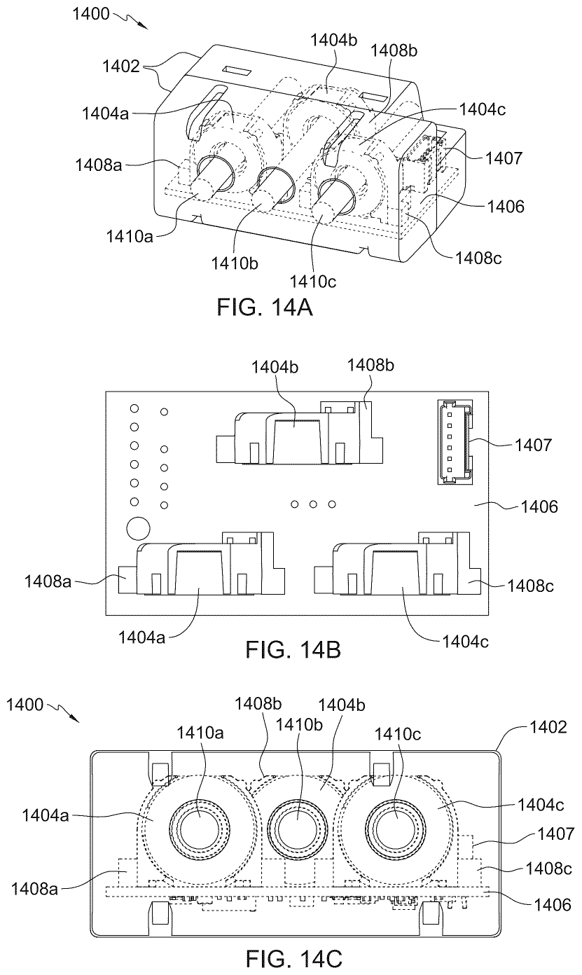

Aspects of one embodiment of a current sensor are depicted in FIGS. 14A-14D and described with reference thereto. FIG. 14A depicts a front perspective view of current sensor 1400, FIG. 14B depicts a top view of current sensor 1400, FIG. 14C depicts a front view of current sensor 1400, and FIG. 14D depicts an exploded front perspective view of current sensor 1400.

The current sensor 1400 includes a two-piece plastic housing 1402 enclosing a current sense module that includes a current sensor PCB 1406, a wound toroid for each power phase (e.g., three toroids 1404a, 1404b, 1404c in this example), a connector port 1407 for accommodating a communication cable that couples to another PCB of the electrical switch device into which current sensor 1400 is incorporated, and mounting brackets 1408a, 1408b, 1408c (one for each wound toroid) mounted to the PCB 1406. Each mounting bracket is configured to maintain a respective toroid in a fixed position relative to the PCB 1406. The mounting brackets 1408a, 1408b, 1408c in this example are mounted to the PCB 1406 to extend substantially perpendicularly from the PCB such that they are positioned for the phase conductors to pass through the toroids in a direction parallel to the PCB (see FIG. 14A).

The current sensor 1400 senses current of the three (in this example) phases corresponding to carriers/wires, segments of which are shown as 1410a, 1410b, and 14010c in FIGS. 14A and 14C. For instance, each toroid 1404a, 1404b, 1404c is configured for a respective phase conductor of the input power phase conductors to pass through the toroid element and provide to the PCB 1406 an output signal proportional to current through the phase conductor passing through the toroid.

The current sensor 1400 could be installed on the line side or the load side of the internal load switch. Thus, in one embodiment the wires 1410a, 1410b, 1410c are line wires/conductors and the sensor 1400 is installed between the power source and input terminals of the internal load switch. Alternatively, the wires 1410a, 1410b, 1410c are load wires/conductors and the sensor 1400 is installed between the output terminals of the internal load switch and the load.

In the depicted arrangement, the toroids and mounting brackets are vertically mounted to the PCB board 1406.

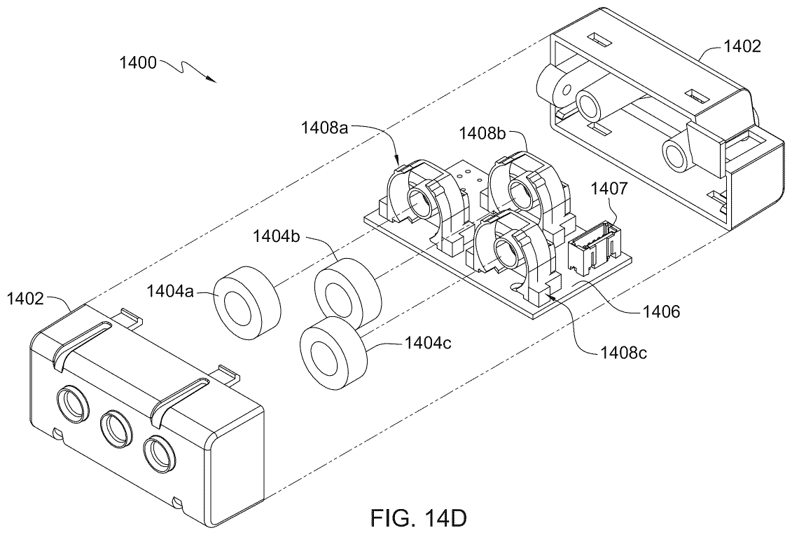

Another embodiment of a current sensor in accordance with aspects described herein is depicted in FIGS. 15A-15C and described with reference thereto. FIGS. 15A-15B each depict a front perspective view of current sensor 1500. Current sensor 1500, like current sensor 1400, senses current of each of three phases on three carrier wires 1510a, 1510b, 1510c, and includes components such as a PCB, toroids, mounting brackets therefor enclosed in housing 1502. Current sensor 1500 also includes in this example a clip 1584 for wire management. The clip is configured to maintain one or more conductors, such as wires 1410a, 1410b, 1410c and/or other conductors, proximate the current sensor. For instance, the clip is shaped and coupled to the current sensor to form an opening between the current sensor housing and the clip. In FIG. 15A, the top end of the clip 1584 can be temporarily pulled away from the current sensor housing so the conductor(s) can be slid into the opening (i.e. between the top end of the clip and the current sensor housing) such that the conductor(s) pass through the opening defined by the clip and current sensor housing and are constrained within that opening unless the top end of the clip 1584 is again pulled away from the current sensor housing.

FIG. 15A depicts a front perspective view of current sensor 1500 mounted to DIN rail 1556. The mounting is facilitated by a DIN mounting clip 1580 secured to the sensor 1500 by screw 1582 (as seen FIG. 15B).

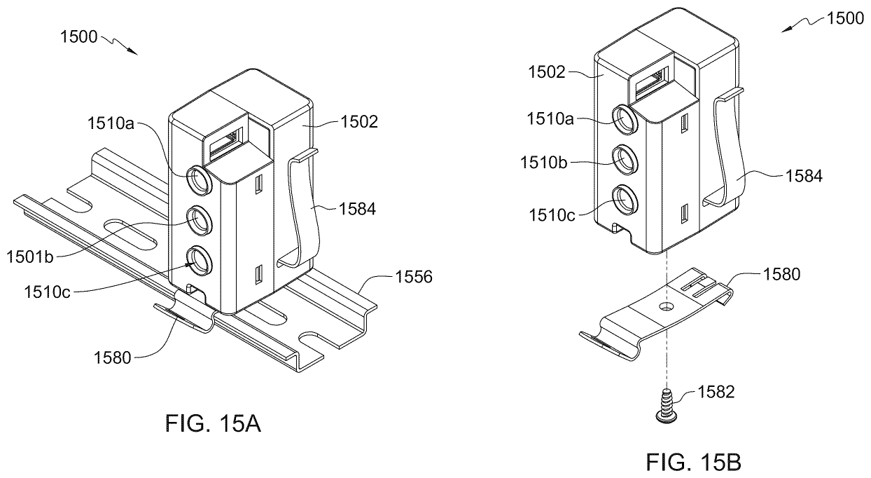

FIG. 16 depicts yet another embodiment of a current sensor, 1600, in which components of the current sensor, including a PCB, toroids, mounting brackets, and communication port (not shown) are arranged in a square/cube shaped enclosure 1602.

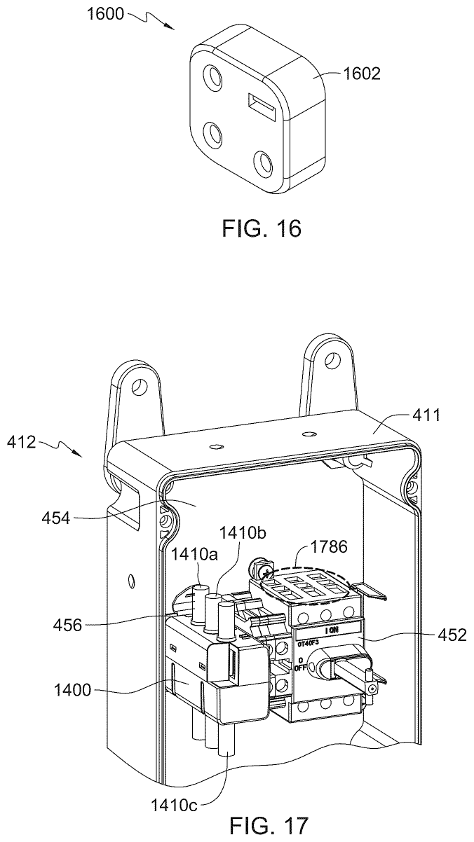

A current sensor as described herein can be mounted in the enclosure of the electrical switch device in any of various positions. FIG. 17 depicts an example vertical mount position. A portion of base subassembly 412 (FIG. 5) is shown including back cover 411, base plate 454, load switch 452 mounted to DIN rail 456, and current sensor 1400 mounted to DIN rail 465 via a mounting clip (not depicted). Here, the current sensor is over the DIN rail 456 with the carrier wires 1410a, 1410b, 1410c passing through the current sensor 1400. Only a segment of the carrier wires 1410a, 1410b, 1410c are shown in FIG. 17 herein but it is understood that they would extend to and terminate at a corresponding three terminals 1786 of the load switch 452.

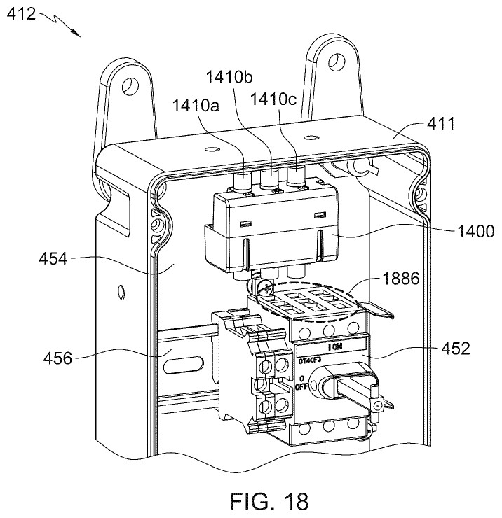

FIG. 18 depicts an example horizontal mount position. A portion of base subassembly 412 (FIG. 5) is shown including back cover 411, base plate 454, load switch 452 mounted to DIN rail 456, and current sensor 1400 mounted above current sensor 1400 through which carrier wires 1410a, 1410b, 1410c pass and terminate at terminals 1886 of load switch 452.

Accordingly, provided is a current sensor optionally mounted on a DIN rail or other component of an electrical switch device and coupled to PCB(s) of the electrical switch device to sense and inform of current passing through any of multiple carrier wires coupled to the switch.

Current sensors as described herein could be applied to other electrical devices, for instance the electrical devices described with reference to FIGS. 1 and 2. Referring to FIGS. 1 and 2, a current sensor as described herein could be provided on a line side of the internal load switch 130, 230 between the incoming phase wires and the load switch 130, 230, for instance.

In embodiments, the electrical switch device communicates with one or more remote computer systems. User can utilize software installed on a user computer system, for instance a mobile application installed on a mobile device such as a smartphone, to access status information about the electrical switch device, for instance any information that may be conveyed by LED lights of the electrical switch device (e.g. voltage presents, ground presence, etc.). The LED lights could provide an indication of current sensed for each power phase(s) entering of the switch, and this status information could be also communicated via one or more remote computer systems to a user application (e.g., mobile app) via the communication board 434. The user can use the user application to monitor the status of current passing through the individual power phases. As an enhancement, the user application could be configurable by the user to raise alerts (notifications, text messages, sounds, etc.) based on set pre-configured current thresholds that the user configures.

Provided is a small sampling of embodiments described herein:
A1. An electrical switch device for supplying power to a load, the electrical switch device comprising: a printed circuit board (PCB), the PCB comprising a communication circuit configured to communicate with a remote device and a processing circuit; a handle configured to rotate between a first position and a second position; a load switch arranged and configured to open and close to selectively supply power to the load; a magnet; and a magnetic sensor configured to sense a magnetic field emanating from the magnet; wherein rotation of the handle between the first position and the second position causes rotational motion of at least one of the magnet and the magnetic sensor, the rotational motion repositioning the magnet and the magnetic sensor relative to each other, and wherein the magnetic sensor is configured to sense the repositioning and output a signal to the processing circuit indicative of a position of the handle.
A2. The electrical switch device of A1, wherein rotation of the handle between the first position and the second position causes the load switch to open and close.
A3. The electrical switch device of A1, further comprising a component configured to rotate based on rotation of the handle between the first position and the second position, wherein the magnet is coupled to the component.
A4. The electrical switch device of A3, wherein rotation of the handle between the first position and the second position causes rotational motion of the magnet to move the magnet closer to, or farther from, the magnetic sensor.
A5. The electrical switch device of A2, A3, or A4 wherein the component is a handle shaft, and wherein the magnet is disposed at least partially embedded in the handle shaft.
A6. The electrical switch device of A1, A2, A3, A4 or A5, further comprising a stop plate disposed between the magnet and the magnetic sensor, wherein the stop plate comprises an opening, and wherein when the handle is positioned in the first position, the magnet is closer to the opening of the stop plate than when the handle is positioned in the second position.
A7. The electrical switch device of A6, wherein based on the handle being in the first position, the magnet is in one position that is at least partially aligned with the opening of the stop plate, and wherein based on the handle being in the second position the magnet is in another position that is out-of-alignment with the opening of the stop plate.
A8. The electrical switch device of A7, wherein the magnetic sensor is configured to sense the magnetic field emanating from the magnet in the one position based on the handle being in the first position, wherein the intensity of the magnetic field emanating from the magnet as sensed by the magnetic sensor is greater when the handle is in the first position and the magnet is in the one position as compared to when the handle is in the second position and the magnet is in the another position.
A9. The electrical switch device of A8, wherein the one position, in which the magnet is at least partially aligned with the opening of the stop plate, corresponds to an OFF position in which the load switch is open, and wherein the another position, in which the magnet is out-of-alignment with the opening of the stop plate, corresponds to an ON position in which the load switch is closed to provide the power to the load.
A10. The electrical switch device of A6, A7, A8 or A9, wherein the stop plate comprises material with a shielding property that shields the magnetic field sensor from the magnetic field emanating from the magnet when the handle is positioned in the second position, and wherein the opening of the stop plate is positioned and configured such that when the handle is positioned in the first position, the magnetic field sensor senses the magnet field emanating from the magnet passes through the opening in the stop plate.
A11. The electrical switch device of A1, A2, A3, A4, A5, A6, A7, A8, A9 or A10, wherein the electrical switch device comprises a stacked board arrangement in which the magnet, the magnetic sensor, and the PCB are provided in a stacked configuration coupled together and at least partially enclosed in a cover of the electrical switch device.
A12. The electrical switch device of A1, A2, A3, A4, A5, A6, A7, A8, A9, A10 or A11, wherein the load switch is configured to accept a plurality of input power phase conductors, and wherein the electrical switch device further comprises a current sensor configured to sense a respective level of current through each phase conductor of the plurality of input power phase conductors and communicate, via a PCB of the current sensor, the sensed respective level of current through each phase conductor to another component of the electrical switch device.
A13. The electrical switch device of A12, further comprising a clip coupled to the current sensor, the clip configured to maintain one or more conductors proximate the current sensor.
B1. An electrical device comprising: a cover subassembly configured for operatively coupling with a handle, the cover subassembly comprising: a printed circuit board (PCB), the PCB comprising a communication circuit configured to communicate with a remote device and a processing circuit; a magnet; and a magnetic sensor configured to sense a magnetic field emanating from the magnet; wherein the cover subassembly is configured such that rotation of the handle between the first position and the second position causes rotational motion of at least one of the magnet and the magnetic sensor, the rotational motion repositioning the magnet and the magnetic sensor relative to each other, and wherein the magnetic sensor is configured to sense the repositioning and output a signal to the processing circuit indicative of a position of the handle.
B2. The electrical device of B1, wherein the cover subassembly further comprises a component configured to rotate based on rotation of the handle between the first position and the second position, wherein the magnet is coupled to the component.
B3. The electrical device of B2, wherein the cover subassembly is configured such that rotation of the handle between the first position and the second position causes rotational motion of the magnet to move the magnet closer to, or farther from, the magnetic sensor.
B4. The electrical device of B2 or B3, wherein the component is a handle shaft, and wherein the magnet is disposed at least partially embedded in the handle shaft.
B5. The electrical device of B1, B2, B3 or B4, wherein the cover subassembly further comprises a stop plate disposed between the magnet and the magnetic sensor, wherein the stop plate comprises an opening, and wherein the cover subassembly is configured such that when the handle is positioned in the first position, the magnet is closer to the opening of the stop plate than when the handle is positioned in the second position.
B6. The electrical device of B5, wherein the cover subassembly is configured such that the magnet is in one position that is at least partially aligned with the opening of the stop plate based on the handle being in the first position, and the magnet is in another position that is out-of-alignment with the opening of the stop plate based on the handle being of the second position.
B7. The electrical device of B6, wherein the magnetic sensor is configured to sense the magnetic field emanating from the magnet in the one position based on the handle being in the first position, wherein the intensity of the magnetic field emanating from the magnet as sensed by the magnetic sensor is greater when the handle is in the first position and the magnet is in the one position as compared to when the handle is in the second position and the magnet is in the another position.
B8. The electrical device of B7, wherein the one position, in which the magnet is at least partially aligned with the opening of the stop plate, corresponds to an OFF position, and wherein the another position, in which the magnet is out-of-alignment with the opening of the stop plate, corresponds to an ON position.
B9. The electrical device of B5, B6, B7 or B8, wherein the stop plate comprises material with a shielding property that shields the magnetic field sensor from the magnetic field emanating from the magnet when the handle is positioned in the second position, and wherein the opening of the stop plate is positioned and configured such that when the handle is positioned in the first position, the magnetic field sensor senses the magnet field emanating from the magnet passes through the opening in the stop plate.
B10. The electrical device of B1, B2, B3, B4, B5, B6, B7, B8 or B9, wherein the cover subassembly comprises a stacked board arrangement in which the magnet, magnetic sensor, and the PCB are provided in a stacked configuration coupled together and at least partially enclosed in a cover of the cover subassembly.
B11. The electrical device of B1, B2, B3, B4, B5, B6, B7, B8, B9 or B10, further comprising: the handle; a base subassembly, the base subassembly comprising a DIN rail and a load switch coupled to the DIN rail, the load switch arranged and configured to open and close to selectively supply power to a load; and a switch rod coupling the load switch to the cover subassembly, wherein rotation of the handle between the first position and the second position causes rotation of the switch rod to open and close the load switch.
B12. The electrical device of B11, wherein the load switch is configured to accept a plurality of input power phase conductors, and wherein the electrical device further comprises a current sensor configured to sense a respective level of current through each phase conductor of the plurality of input power phase conductors and communicate, via a PCB of the current sensor, the sensed respective level of current through each phase conductor to another component of the electrical switch device.
B13. The electrical switch device of B12, further comprising a clip coupled to the current sensor, the clip configured to maintain one or more conductors proximate the current sensor.

Although various examples are provided, variations are possible without departing from a spirit of the claimed aspects.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components and/or groups thereof.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description, but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. An electrical switch device for supplying power to a load, the electrical switch device comprising:
a printed circuit board (PCB), the PCB comprising a communication circuit configured to communicate with a remote device and a processing circuit;
a handle configured to rotate between a first position and a second position;
a load switch arranged and configured to open and close to selectively supply power to the load;
a magnet; and
a magnetic sensor configured to sense a magnetic field emanating from the magnet;
wherein rotation of the handle between the first position and the second position causes rotational motion of at least one of the magnet and the magnetic sensor, the rotational motion repositioning the magnet and the magnetic sensor relative to each other, and wherein the magnetic sensor is configured to sense the repositioning and output a signal to the processing circuit indicative of a position of the handle.

2. The electrical switch device of claim 1, wherein rotation of the handle between the first position and the second position causes the load switch to open and close.

3. The electrical switch device of claim 1, further comprising a component configured to rotate based on rotation of the handle between the first position and the second position, wherein the magnet is coupled to the component.

4. The electrical switch device of claim 3, wherein rotation of the handle between the first position and the second position causes rotational motion of the magnet to move the magnet closer to, or farther from, the magnetic sensor.

5. The electrical switch device of claim 3, wherein the component is a handle shaft, and wherein the magnet is disposed at least partially embedded in the handle shaft.

6. The electrical switch device of claim 1, further comprising a stop plate disposed between the magnet and the magnetic sensor, wherein the stop plate comprises an opening, and wherein when the handle is positioned in the first position, the magnet is closer to the opening of the stop plate than when the handle is positioned in the second position.

7. The electrical switch device of claim 6, wherein based on the handle being in the first position, the magnet is in one position that is at least partially aligned with the opening of the stop plate, and wherein based on the handle being in the second position the magnet is in another position that is out-of-alignment with the opening of the stop plate.

8. The electrical switch device of claim 7, wherein the magnetic sensor is configured to sense the magnetic field emanating from the magnet in the one position based on the handle being in the first position, wherein the intensity of the magnetic field emanating from the magnet as sensed by the magnetic sensor is greater when the handle is in the first position and the magnet is in the one position as compared to when the handle is in the second position and the magnet is in the another position.

9. The electrical switch device of claim 8, wherein the one position, in which the magnet is at least partially aligned with the opening of the stop plate, corresponds to an OFF position in which the load switch is open, and wherein the another position, in which the magnet is out-of-alignment with the opening of the stop plate, corresponds to an ON position in which the load switch is closed to provide the power to the load.

10. The electrical switch device of claim 6, wherein the stop plate comprises material with a shielding property that shields the magnetic field sensor from the magnetic field emanating from the magnet when the handle is positioned in the second position, and wherein the opening of the stop plate is positioned and configured such that when the handle is positioned in the first position, the magnetic field sensor senses the magnet field emanating from the magnet passes through the opening in the stop plate.

11. The electrical switch device of claim 1, wherein the electrical switch device comprises a stacked board arrangement in which the magnet, the magnetic sensor, and the PCB are provided in a stacked configuration coupled together and at least partially enclosed in a cover of the electrical switch device.

12. The electrical switch device of claim 1, wherein the load switch is configured to accept a plurality of input power phase conductors, and wherein the electrical switch device further comprises a current sensor configured to sense a respective level of current through each phase conductor of the plurality of input power phase conductors and communicate, via a PCB of the current sensor, the sensed respective level of current through each phase conductor to another component of the electrical switch device.

13. The electrical switch device of claim 12, further comprising a clip coupled to the current sensor, the clip configured to maintain one or more conductors proximate the current sensor.

14. An electrical device comprising:
a cover subassembly configured for operatively coupling with a handle, the cover subassembly comprising:
a printed circuit board (PCB), the PCB comprising a communication circuit configured to communicate with a remote device and a processing circuit;
a magnet; and
a magnetic sensor configured to sense a magnetic field emanating from the magnet;
wherein the cover subassembly is configured such that rotation of the handle between the first position and the second position causes rotational motion of at least one of the magnet and the magnetic sensor, the rotational motion repositioning the magnet and the magnetic sensor relative to each other, and wherein the magnetic sensor is configured to sense the repositioning and output a signal to the processing circuit indicative of a position of the handle.

15. The electrical device of claim 14, wherein the cover subassembly further comprises a component configured to rotate based on rotation of the handle between the first position and the second position, wherein the magnet is coupled to the component.

16. The electrical device of claim 15, wherein the cover subassembly is configured such that rotation of the handle between the first position and the second position causes rotational motion of the magnet to move the magnet closer to, or farther from, the magnetic sensor.

17. The electrical device of claim 15, wherein the component is a handle shaft, and wherein the magnet is disposed at least partially embedded in the handle shaft.

18. The electrical device of claim 14, wherein the cover subassembly further comprises a stop plate disposed between the magnet and the magnetic sensor, wherein the stop plate comprises an opening, and wherein the cover subassembly is configured such that when the handle is positioned in the first position, the magnet is closer to the opening of the stop plate than when the handle is positioned in the second position.

19. The electrical device of claim 18, wherein the cover subassembly is configured such that the magnet is in one position that is at least partially aligned with the opening of the stop plate based on the handle being in the first position, and the magnet is in another position that is out-of-alignment with the opening of the stop plate based on the handle being of the second position.

20. The electrical device of claim 19, wherein the magnetic sensor is configured to sense the magnetic field emanating from the magnet in the one position based on the handle being in the first position, wherein the intensity of the magnetic field emanating from the magnet as sensed by the magnetic sensor is greater when the handle is in the first position and the magnet is in the one position as compared to when the handle is in the second position and the magnet is in the another position.

21. The electrical device of claim 20, wherein the one position, in which the magnet is at least partially aligned with the opening of the stop plate, corresponds to an OFF position, and wherein the another position, in which the magnet is out-of-alignment with the opening of the stop plate, corresponds to an ON position.

22. The electrical device of claim 18, wherein the stop plate comprises material with a shielding property that shields the magnetic field sensor from the magnetic field emanating from the magnet when the handle is positioned in the second position, and wherein the opening of the stop plate is positioned and configured such that when the handle is positioned in the first position, the magnetic field sensor senses the magnet field emanating from the magnet passes through the opening in the stop plate.

23. The electrical device of claim 14, wherein the cover subassembly comprises a stacked board arrangement in which the magnet, magnetic sensor, and the PCB are provided in a stacked configuration coupled together and at least partially enclosed in a cover of the cover subassembly.

24. The electrical device of claim 23, further comprising:
the handle;
a base subassembly, the base subassembly comprising a DIN rail and a load switch coupled to the DIN rail, the load switch arranged and configured to open and close to selectively supply power to a load; and
a switch rod coupling the load switch to the cover subassembly, wherein rotation of the handle between the first position and the second position causes rotation of the switch rod to open and close the load switch.

25. The electrical device of claim 24, wherein the load switch is configured to accept a plurality of input power phase conductors, and wherein the electrical device further comprises a current sensor configured to sense a respective level of current through each phase conductor of the plurality of input power phase conductors and communicate, via a PCB of the current sensor, the sensed respective level of current through each phase conductor to another component of the electrical switch device.

26. The electrical switch device of claim 25, further comprising a clip coupled to the current sensor, the clip configured to maintain one or more conductors proximate the current sensor.
